(19) United States
(12) Patent Application Publication
(10) Pub. No.: US 2026/0246451 A1
(43) Pub. Date: Aug. 20, 2026

(54) ACOUSTIC WAVE DEVICE AND MULTIPLEXER

(71) Applicant: Murata Manufacturing Co., Ltd., Nagaokakyo-shi (JP)

(72) Inventor: Kenta MAEDA, Nagaokakyo-shi (JP)

(21) Appl. No.: 19/637,101

(22) Filed: Apr. 2, 2026

Related U.S. Application Data
(63) Continuation of application No. PCT/JP2024/035520, filed on Oct. 3, 2024.

(30) Foreign Application Priority Data
Oct. 17, 2023 (JP) 2023-178757

(51) Int. Cl. H03H 9/64; H03H 9/145; H03H 9/72

(52) U.S. Cl. CPC H03H 9/6496; H03H 9/14541; H03H 9/6409; H03H 9/72; H03H 9/6483

(57) ABSTRACT

A filter includes multiple acoustic wave resonant circuits. Among the multiple acoustic wave resonant circuits, an acoustic wave resonant circuit includes series-arm resonators connected in series with one another. Each of the series-arm resonators includes an IDT electrode on a piezoelectric substrate, and multiple electrode fingers parallel or substantially parallel to one another. The IDT electrode included in each of the acoustic wave resonators is divided into multiple electrode-finger regions including different duties and defined as a region where two or more electrode fingers including an equal duty are consecutively arranged. When the multiple electrode-finger regions are compared, an electrode-finger pitch, which is an interval between adjacent electrode fingers, decreases as a duty increases.

### CROSS REFERENCE TO RELATED APPLICATIONS

This application claims the benefit of priority to Japanese Patent Application No. 2023-178757 filed on Oct. 17, 2023 and is a Continuation Application of PCT Application No. PCT/JP2024/035520 filed on Oct. 3, 2024. The entire contents of each application are hereby incorporated herein by reference.

### BACKGROUND OF THE INVENTION

### 1. Field of the Invention

The present invention relates to acoustic wave devices and multiplexers.

### 2. Description of the Related Art

International Publication No. WO 2018/003297 discloses a filter (acoustic wave device) having multiple series-divided surface acoustic wave resonators. It is described that stopband ripple can be reduced or prevented by making the parameters of IDT (InterDigital Transducer) electrodes of the surface acoustic wave resonators different from one another. Japanese Unexamined Patent Application Publication No. 2005-005853 discloses that stopband ripple can be reduced or prevented by narrowing the width of the electrode fingers of a surface acoustic wave resonator toward an end portion of the IDT electrode.

However, in the acoustic wave devices disclosed in International Publication No. WO 2018/003297 and Japanese Unexamined Patent Application Publication No. 2005-005853, the suppression of Rayleigh wave ripples generated on the lower frequency side of the fundamental wave is insufficient.

### SUMMARY OF THE INVENTION

Example embodiments the present invention provide surface acoustic wave devices and multiplexers in each of which Rayleigh wave ripples are reduced or prevented.

An acoustic wave device according an example embodiment of the present invention includes multiple acoustic wave resonant circuits. Among the multiple acoustic wave resonant circuits, a first acoustic wave resonant circuit includes multiple acoustic wave resonators connected in series with one another. Each of the multiple acoustic wave resonators includes an IDT (InterDigital Transducer) electrode on a piezoelectric substrate and including multiple electrode fingers parallel or substantially parallel to one another. The IDT electrode included in each of the multiple acoustic wave resonators is divided into multiple electrode-finger regions including different duties, each electrode-finger region being defined as a region where two or more electrode fingers with an equal duty are consecutively arranged. When the multiple electrode-finger regions are compared, an electrode-finger pitch, which is an interval between adjacent electrode fingers, decreases as the duty increases.

According to example embodiments of the present invention, acoustic wave devices and multiplexers are provided in each of which Rayleigh wave ripples are reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram of a multiplexer according to an example embodiment of the present invention.

FIG. 2 is a circuit configuration diagram of an acoustic wave device according to Example 1 of an example embodiment of the present invention.

FIG. 3A includes a plan view and cross-sectional views schematically illustrating a first example of an acoustic wave resonator defining a portion of an acoustic wave device according to an example embodiment of the present invention.

FIG. 3B is a cross-sectional view schematically illustrating a second example of an acoustic wave resonator defining a portion of an acoustic wave device according to an example embodiment of the present invention.

FIG. 4 is a plan view illustrating an electrode configuration of a first acoustic wave resonant circuit according to Example 1 of an example embodiment of the present invention.

FIG. 5 is a plan view illustrating an electrode configuration of an acoustic wave resonator defining a portion of the first acoustic wave resonant circuit according to Example 1 an example embodiment of the present invention.

FIG. 6 is a plan view illustrating an electrode configuration of an acoustic wave resonant circuit according to Comparative Example 1.

FIG. 7A is a graph representing the transmission characteristics of filters according to Example 1 and Comparative Example 1.

FIG. 7B is a graph representing the transmission characteristics in the vicinity of a stopband of the filters according to Example 1 of an example embodiment of the present invention and Comparative Example 1.

FIG. 7C is a graph representing the transmission characteristics in the vicinity of a frequency band in which a Rayleigh wave mode is generated, of the filters according to Example 1 of an example embodiment of the present invention and Comparative Example 1.

FIG. 8 is a graph representing the resonance characteristics of an acoustic wave resonator.

FIG. 9A is a graph representing resonance characteristics of a main mode when the duty of an acoustic wave resonator is varied.

FIG. 9B is a graph representing resonance characteristics of a Rayleigh wave mode when the duty of the acoustic wave resonator is varied.

FIG. 10A is a graph representing resonance characteristics of the main mode when an electrode-finger pitch is corrected in response to variations in the duty of an acoustic wave resonator.

FIG. 10B is a graph representing resonance characteristics of the Rayleigh wave mode when the electrode-finger pitch is corrected in response to variations in the duty of an acoustic wave resonator.

FIGS. 11A and 11B include graphs representing variations in Rayleigh wave ripples when the number of electrode fingers in each region of an acoustic wave resonator is varied.

FIG. 12 is a graph representing variations in Rayleigh wave ripples when the difference in duty between regions of an acoustic wave resonator is varied.

FIG. 13A is a plan view illustrating an electrode configuration of a first acoustic wave resonant circuit according to Example 2 of an example embodiment of the present invention.

FIG. 13B is a plan view illustrating an electrode configuration of a first acoustic wave resonant circuit according to Example 3 of an example embodiment of the present invention.

FIG. 13C is a plan view illustrating an electrode configuration of an acoustic wave resonant circuit according to Comparative Example 2.

FIG. 14 is a graph representing the Rayleigh wave ripples of the acoustic wave devices according to Example 2 of an example embodiment of the present invention, Example 3 of an example embodiment of the present invention, and Comparative Example 2.

FIG. 15 is a plan view illustrating an electrode configuration of a first acoustic wave resonant circuit according to Example 4 of an example embodiment of the present invention.

FIG. 16 is a plan view illustrating an electrode configuration of a first acoustic wave resonant circuit according to Example 5 of an example embodiment of the present invention.

FIG. 17 is a circuit configuration diagram of an acoustic wave device according to Example 6 of an example embodiment of the present invention.

FIG. 18A is a plan view illustrating an electrode configuration of an acoustic wave resonator defining a portion of a first acoustic wave resonant circuit according to Example 7 of an example embodiment of the present invention.

FIG. 18B is a plan view illustrating an electrode configuration of an acoustic wave resonator defining a portion of a first acoustic wave resonant circuit according to Example 8 of an example embodiment of the present invention.

FIG. 18C is a plan view illustrating an electrode configuration of an acoustic wave resonator defining a portion of a first acoustic wave resonant circuit according to Example 9 of an example embodiment of the present invention.

FIG. 19A is a plan view illustrating an electrode configuration of an acoustic wave resonator defining a portion of a first acoustic wave resonant circuit according to Modification 1 of an example embodiment of the present invention.

FIG. 19B is a plan view illustrating an electrode configuration of an acoustic wave resonator defining a portion of a first acoustic wave resonant circuit according to Modification 2 of an example embodiment of the present invention.

### DETAILED DESCRIPTION OF THE EXAMPLE EMBODIMENTS

Hereinafter, example embodiments of the present disclosure will be described in detail with reference to the drawings. The example embodiments described below are provided only as examples, whether broadly or specifically defined. The numerical values, shapes, materials, components, arrangement and connection configurations of the components, and the like described in the following example embodiments are merely examples and are not intended to limit the present invention.

Each drawing is a schematic diagram in which emphasis, omission, or adjustment of proportions has been made as appropriate to illustrate example embodiments of the present invention, and is not necessarily to scale. Thus, they may differ from the actual shapes, positional relationships, and proportions. In the drawings, the same reference numerals are given to identical or substantially identical configurations, and repeated explanations may be omitted or simplified.

In the circuit configuration described in the present disclosure, the expression “connected between A and B” refers to being connected to both A and B between A and B.

In addition, in the component arrangement described in the present disclosure, the expression “component A is arranged in series in path B” means that both of a signal input terminal and a signal output terminal of component A are connected to wiring, electrodes, or terminals that define path B.

Furthermore, terms indicating relationships between elements, such as “parallel” and “perpendicular”, terms indicating shapes of elements, such as “rectangular”, and numerical ranges are not intended to indicate only strict meanings, but also include substantially equivalent ranges, for example, variations on the order of several percent.

Additionally, in the present disclosure, the term “terminal” refers to a point at which a conductor within an element terminates. When the impedance of a conductor between elements is sufficiently low, a terminal is interpreted not only as a single point but also as any point on the conductor between the elements, or as the entire conductor.

In the following example embodiments of the present invention, the passband of an acoustic wave device or a filter is defined as a frequency band between two frequencies at which the insertion loss is, for example, about 3 dB higher than the minimum insertion loss within the passband.

Moreover, in the present disclosure, Band A and Band B refer to frequency bands defined in advance by a standardization organization or the like (e.g., 3GPP (registered trademark), IEEE (Institute of Electrical and Electronics Engineers), etc.) for communication systems constructed using Radio Access Technology (RAT). In the present example embodiment, examples of the communication systems include, but are not limited to, LTE (Long Term Evolution) systems, 5G (5th Generation)-NR (New Radio) systems, and WLAN (Wireless Local Area Network) systems.

An uplink operation band of Band A refers to a frequency range within Band A that is designated for uplink. A downlink operation band of Band A refers to a frequency range within Band A that is designated for downlink.

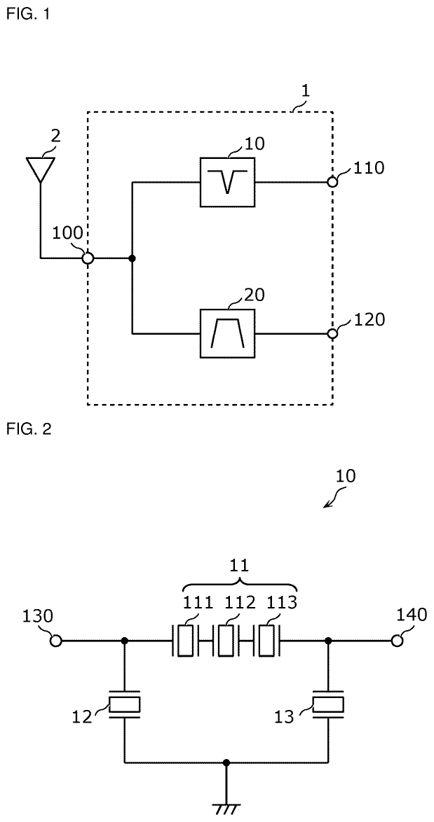

FIG. 1 is a circuit configuration diagram of a multiplexer 1 according to an example embodiment of the present invention. The multiplexer 1 includes filters 10 and 20, a common terminal 100, and input/output terminals 110 and 120. The common terminal 100 is connected to, for example, an antenna 2.

The filter 10 is an example of an acoustic wave device, is connected to the common terminal 100, and is, for example, a band-stop filter having a stopband. The filter 20 is connected to the common terminal 100, and is, for example, a band-pass filter having a passband. In the present example embodiment, the stopband of the filter 10 and the passband of the filter 20 at least partially overlap, and the multiplexer 1 defines an extractor.

The filter 10 according to the present example embodiment is able to reduce or prevent Rayleigh wave ripples because an acoustic wave resonator for providing a stopband has an IDT electrode configuration described later. It is thus possible to reduce or prevent deterioration of the transmission characteristics in the passband of the filter 10, located on the lower-frequency side of the stopband of the filter 10.

Additionally, since a signal in the Rayleigh wave mode generated in the filter 10 can be reduced or prevented from coupling into the filter 20 through the common terminal 100, deterioration of attenuation characteristics of the filter 20 can be reduced or prevented.

The filter 10 is not limited to a band-stop filter, and may be, for example, a band-pass filter, a low-pass filter, or a high-pass filter. If the filter 10 is a band-pass filter, it can reduce or prevent Rayleigh wave ripples generated on the lower frequency side of the passband of the filter 10. Additionally, since a signal in the Rayleigh wave mode generated in the filter 10 can be reduced or prevented from coupling into the filter 20 through the common terminal 100, deterioration of transmission characteristics or attenuation characteristics of the filter 20 can be reduced or prevented.

FIG. 2 is a circuit configuration diagram of the filter 10 according to Example 1 of an example embodiment of the present invention. The filter 10 illustrated in FIG. 2 is an example of the filter 10 defining a portion of the multiplexer 1 according to the present example embodiment. The filter 10 according to Example 1 is an example of an acoustic wave device and includes multiple acoustic wave resonant circuits. Specifically, the filter 10 includes series-arm resonators 111, 112, and 113, parallel-arm resonators 12 and 13, and terminals 130 and 140. The terminal 130 is connected to the common terminal 100.

The series-arm resonators 111, 112, and 113 define a first acoustic wave resonant circuit (acoustic wave resonant circuit 11). Additionally, the parallel-arm resonator 12 defines a second acoustic wave resonant circuit, and the parallel-arm resonator 13 defines a third acoustic wave resonant circuit.

The series-arm resonators 111, 112, and 113 are acoustic wave resonators connected in series with one another between the terminal 130 and the terminal 140, and define a divided resonator group.

The divided resonator group is defined as a resonant circuit including multiple acoustic wave resonators connected in series with one another, in which no circuit elements other than the multiple acoustic wave resonators, nor ground, are connected to connection nodes that connect the multiple acoustic wave resonators.

The parallel-arm resonator 12 is an acoustic wave resonator and is connected between a connection point of the terminal 130 and the series-arm resonator 111, and ground. The parallel-arm resonator 13 is an acoustic wave resonator and is connected between a connection point of the series-arm resonator 113 and the terminal 140, and ground.

In the above configuration of the filter 10, from the lower frequency side, a resonant frequency defined by the acoustic wave resonant circuit 11, an anti-resonant frequency defined by the acoustic wave resonant circuit 11 and resonant frequencies defined by the parallel-arm resonators 12 and 13, and anti-resonant frequencies defined by the parallel-arm resonators 12 and 13 are arranged in this order. As a result, the filter 10 defines and functions as a band-stop filter whose stopband includes the anti-resonant frequency defined by the acoustic wave resonant circuit 11 and the resonant frequencies defined by the parallel-arm resonators 12 and 13.

Each of the series-arm resonators 111 to 113 includes an IDT electrode disposed on a substrate having piezoelectric properties.

Each of the parallel-arm resonators 12 and 13 is not necessarily an acoustic wave resonator and may instead be, for example, a resonant circuit including an inductor and a capacitor.

In addition, the circuit configuration of the filter 10 illustrated in FIG. 2 is one example. The number of acoustic wave resonant circuits is not limited to three, and it is sufficient that the number of acoustic wave resonant circuits is one or more in the series-arm path and one or more in the parallel-arm path.

The divided resonator group including multiple acoustic wave resonators connected in series with one another is not limited to being included in the acoustic wave resonant circuit 11, and may instead be included in the parallel-arm resonator 12 or 13.

Furthermore, the number of acoustic wave resonators of the divided resonator group is not limited to three, which is illustrated by way of example in the acoustic wave resonant circuit 11, and may instead be two or more, for example.

An inductor may be connected between at least one of the parallel-arm resonators 12 and 13, and ground.

The filter 10 is not limited to a ladder filter, and may instead be, for example, a filter including a longitudinally coupled resonator unit in which multiple acoustic wave resonators are arranged side by side in an acoustic wave propagation direction.

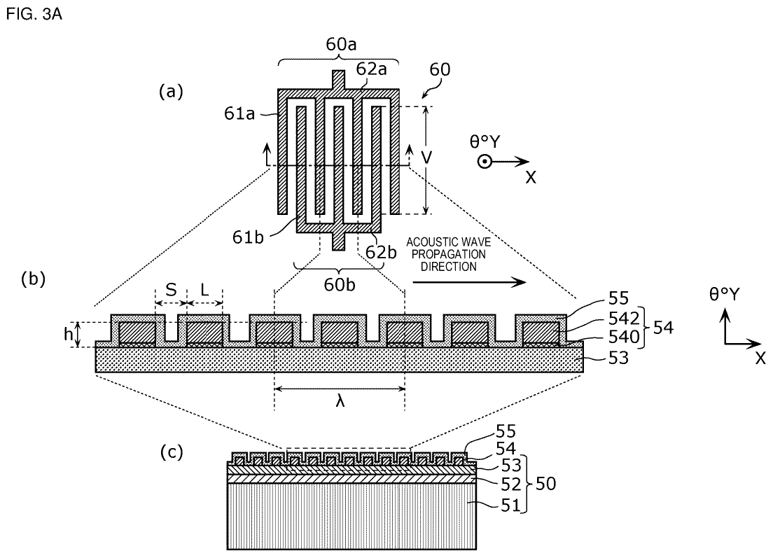

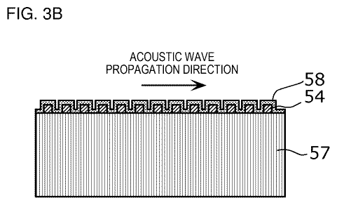

Next, the basic structure of an acoustic wave resonator of a portion of the filter 10 will be described. FIG. 3A includes a plan view and cross-sectional views schematically illustrating a first example of the acoustic wave resonator defining a portion of the filter 10 according to the present example embodiment. In the diagram, the basic structure of the acoustic wave resonator of a portion of the filter 10 is illustrated by way of the present example. An acoustic wave resonator 60 illustrated in FIG. 3A is for explaining a typical structure of the acoustic wave resonator of a portion of the filter 10, and the number, length, and the like of the electrode fingers of each electrode are not limited thereto.

The acoustic wave resonator 60 includes a piezoelectric substrate 50, and comb-shaped electrodes 60a and 60b. As illustrated in portion (a) of FIG. 3A, the pair of comb-shaped electrodes 60a and 60b, which face each other, is provided on the piezoelectric substrate 50. The comb-shaped electrode 60a includes multiple electrode fingers 61a parallel or substantially parallel to one another, and a busbar electrode 62a connecting one end of the multiple electrode fingers 61a. Similarly, the comb-shaped electrode 60b includes multiple electrode fingers 61b parallel or substantially parallel to one another, and a busbar electrode 62b connecting one end of the multiple electrode fingers 61b. The electrode fingers 61a and 61b are provided along a direction orthogonal to the acoustic wave propagation direction (X-axis direction). The busbar electrode 62a and the busbar electrode 62b face each other with the electrode fingers 61a and 61b interposed therebetween. The comb-shaped electrodes 60a and 60b define an IDT electrode 54.

The acoustic wave resonator 60 may include reflectors at both ends of the IDT electrode 54 in the acoustic wave propagation direction (X-axis direction).

As illustrated in portion (b) of FIG. 3A, the IDT electrode 54 includes, for example, a multilayer structure including an adhesive layer 540 and a main electrode layer 542.

The adhesive layer 540 is a layer to improve adhesion between the piezoelectric substrate 50 and the main electrode layer 542, and, for example, Ti is used as a material. As a material of the main electrode layer 542, for example, Al including about 1% Cu is used. A protective layer 55 is provided to cover the comb-shaped electrodes 60a and 60b. The protective layer 55 is a layer to protect the main electrode layer 542 from the external environment, adjust frequency-temperature characteristics, and improve moisture resistance, and is, for example, a dielectric film mainly including silicon dioxide.

The materials of the adhesive layer 540, the main electrode layer 542, and the protective layer 55 are not limited to the materials described above. Furthermore, the IDT electrode 54 is not necessarily configured to include the above-described multilayer structure. For example, the IDT electrode 54 may include a metal or alloy, such as Ti, Al, Cu, Pt, Au, Ag, Pd, or the like, or may include multiple multilayer bodies including the aforementioned metal or alloy. Additionally, the protective layer 55 need not be provided.

Next, the multilayer structure of the piezoelectric substrate 50 will be described.

As illustrated in portion (c) of FIG. 3A, the piezoelectric substrate 50 includes a high-acoustic-velocity support substrate 51, a low-acoustic-velocity film 52, and a piezoelectric film 53, and the piezoelectric substrate 50 includes a structure in which the high-acoustic-velocity support substrate 51, the low-acoustic-velocity film 52, and the piezoelectric film 53 are layered in this order.

The piezoelectric film 53 is made of, for example, a θ° Y-cut X-propagating LiTaO₃ piezoelectric single crystal or piezoelectric ceramics (a lithium tantalate single crystal or ceramics cut along a plane whose normal is an axis rotated by θ° from the Y-axis about the X-axis, in which a surface acoustic wave propagates in the X-axis direction). The material and cut angle θ of the piezoelectric single crystal used as the piezoelectric film 53 are appropriately selected in accordance with the required specifications of each filter.

The high-acoustic-velocity support substrate 51 is a substrate that supports the low-acoustic-velocity film 52, the piezoelectric film 53, and the IDT electrode 54. The high-acoustic-velocity support substrate 51 is a substrate in which the acoustic velocity of bulk waves in the high-acoustic-velocity support substrate 51 is higher than that of acoustic waves such as surface waves and boundary waves propagating through the piezoelectric film 53, and confines surface acoustic waves within a portion where the piezoelectric film 53 and the low-acoustic-velocity film 52 are layered, thus preventing leakage below the high-acoustic-velocity support substrate 51. Examples of the material of the high-acoustic-velocity support substrate 51 include piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, dielectric materials such as aluminum oxide, silicon oxynitride, DLC (diamond-like carbon), or diamond, semiconductors such as silicon, and materials mainly including any of the foregoing materials. The above-described spinel includes, for example, an aluminum compound including one or more elements of Mg, Fe, Zn, Mn, or the like, and oxygen. Examples of the above-described spinel include MgAl₂O₄, FeAl₂O₄, ZnAl₂O₄, or MnAl₂O₄.

The low-acoustic-velocity film 52 is a film in which the acoustic velocity of bulk waves in the low-acoustic-velocity film 52 is lower than that of bulk waves propagating through the piezoelectric film 53, and is disposed between the piezoelectric film 53 and the high-acoustic-velocity support substrate 51. Due to this structure and the property that acoustic waves inherently concentrate their energy in a low-acoustic-velocity medium, leakage of surface acoustic wave energy out of the piezoelectric film 53 is reduced or prevented. Examples of the material of the low-acoustic-velocity film 52 include dielectric materials such as glass, silicon oxide, silicon oxynitride, lithium oxide, or tantalum oxide, compounds obtained by adding fluorine, carbon, or boron to silicon oxide, or materials mainly including any of the foregoing materials.

According to the above-described multilayer structure of the piezoelectric substrate 50, the Q value at the resonant frequency and the anti-resonant frequency can be significantly increased as compared with a conventional structure using a single-layer piezoelectric substrate. That is, since an acoustic wave resonator having a high Q value can be obtained, a filter having a small insertion loss can be configured using this acoustic wave resonator.

The high-acoustic-velocity support substrate 51 may instead have a structure in which a support substrate and a high-acoustic-velocity film in which the acoustic velocity of bulk waves propagating therethrough is higher than that of acoustic waves such as surface waves and boundary waves propagating through the piezoelectric film 53 are layered. In this case, as the material of the high-acoustic-velocity film, the same material as that of the high-acoustic-velocity support substrate 51 can be used. Additionally, examples of the material of the support substrate include piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, or forsterite, dielectric materials such as diamond or glass, semiconductors such as silicon or gallium nitride, resins, or materials mainly including any of the foregoing materials.

In the present specification, the term “main component of a material” refers to a component whose proportion in the material exceeds 50% by weight. The main component may be present in, for example, any of a single-crystal state, a polycrystalline state, or an amorphous state, or in a state in which these states coexist.

FIG. 3B is a cross-sectional view schematically representing a second example of the acoustic wave resonator defining a portion of the filter 10 according to the present example embodiment. In the acoustic wave resonator 60 illustrated in FIG. 3A, an example is illustrated in which the IDT electrode 54 is provided on the piezoelectric substrate 50 including the piezoelectric film 53. However, as illustrated in FIG. 3B, the substrate on which the IDT electrode 54 is provided may instead be a piezoelectric single-crystal substrate 57 including a single-layer piezoelectric layer.

The piezoelectric single-crystal substrate 57 is, for example, made of a piezoelectric single crystal of LiTaO₃. The acoustic wave resonator according to the present example includes the piezoelectric single-crystal substrate 57 of LiTaO₃, the IDT electrode 54, and a protective layer 58 provided on the piezoelectric single-crystal substrate 57 and the IDT electrode 54.

The above-described piezoelectric film 53 and piezoelectric single-crystal substrate 57 may, as appropriate, include the laminated structure, material, cut angle, and thickness varied in accordance the with required transmission characteristics of the filter 10 and the multiplexer 1.

In addition, the piezoelectric substrate on which the IDT electrode 54 is provided may have a structure in which the support substrate, the energy confinement layer, and the piezoelectric film are layered in this order. The IDT electrode 54 is provided on the piezoelectric film. As the piezoelectric film, for example, a LiTaO₃ piezoelectric single crystal or a piezoelectric ceramic may be used. The support substrate is a substrate that supports the piezoelectric film, the energy confinement layer, and the IDT electrode 54.

The energy confinement layer includes one or more layers, and the velocity of bulk acoustic waves propagating through at least one of the layers is higher than the velocity of acoustic waves propagating near the piezoelectric film. For example, the energy confinement layer may have a multilayer structure including a low-acoustic-velocity layer and a high-acoustic-velocity layer. The low-acoustic-velocity layer is a layer in which the acoustic velocity of bulk waves in the low-acoustic-velocity layer is lower than that of acoustic waves propagating through the piezoelectric film. The high-acoustic-velocity layer is a layer in which the acoustic velocity of bulk waves in the high-acoustic-velocity layer is higher than that of acoustic waves propagating through the piezoelectric film. The support substrate may also define and function as a high-acoustic-velocity layer.

Furthermore, the energy confinement layer may be an acoustic impedance layer in which a low-acoustic-impedance layer with a relatively low acoustic impedance and a high-acoustic-impedance layer with a relatively high acoustic impedance are alternately layered.

Here, the electrode parameters of the IDT electrode 54 forming part of the acoustic wave resonator 60 will be described.

The wavelength of the acoustic wave resonator 60 is defined by a wavelength λ, which is the repeating cycle of the multiple electrode fingers 61a or 61b of the IDT electrode 54 illustrated in portion (b) of FIG. 3A. Also, the electrode-finger pitch is about ½ of the wavelength λ, and is the distance between (the center of) an electrode finger 61a and (the center of) an electrode finger 61b that are adjacent to each other. Moreover, the electrode-finger pitch is defined as (L+S), where L denotes the line width of the electrode fingers 61a and 61b of the comb-shaped electrodes 60a and 60b, respectively, and S denotes the space width between the adjacent electrode fingers 61a and 61b.

An overlap width V of the pair of comb-shaped electrodes 60a and 60b is, as illustrated in portion (a) of FIG. 3A, the length of the electrode fingers that overlap when the electrode fingers 61a and 61b are viewed from the acoustic wave propagation direction (X-axis direction). Additionally, a duty D of the electrode fingers of each acoustic wave resonator is the line width occupancy of the multiple electrode fingers 61a and 61b, which is the ratio of the line width of the multiple electrode fingers 61a and 61b to the sum of the line width and the space width, defined as L/(L+S). Also, h denotes the height of the comb-shaped electrodes 60a and 60b. Additionally, Ni denotes the total number of electrode fingers 61a and 61b included in the IDT electrode 54. Hereinafter, parameters related to the shape of the IDT electrode of the acoustic wave resonator, such as the wavelength λ, the electrode-finger pitch, the overlap width V, the duty D, the height h of the IDT electrode 54, and the number of electrode fingers Ni, will be referred to as electrode parameters.

The duty D (=L/(L+S)) is obtained by measuring the line width L and the space width S as follows. The line width L is the length in the X-axis direction of the bonding interface between the electrode finger 61a or 61b and the piezoelectric film 53 when the bonding interface is viewed from the extension direction of the electrode fingers 61a and 61b. The space width S is obtained by subtracting the line width L from the electrode-finger pitch. The electrode-finger pitch is the distance between the center of the bonding interface in the X-axis direction and the center of its adjacent bonding interface in the X-axis direction, when the bonding interface is viewed from the above-described extension direction. The line width L and the space width S are measured by, for example, exposing a cross section perpendicular or substantially perpendicular to the above-described extension direction of the acoustic wave resonator 60 through cutting or the like, and observing the cross section using a scanning microscope or the like.

Also, a region where two or more electrode fingers having an equal duty D are consecutively arranged is defined as an electrode-finger region. The IDT electrode 54 is divided into multiple electrode-finger regions having different duties D.

When the electrode-finger pitch is not constant in each of the electrode-finger regions constituting the IDT electrode 54, the electrode-finger pitch of one electrode-finger region is defined as the average electrode-finger pitch within that electrode-finger region. The average electrode-finger pitch of an electrode-finger region is defined as Dr/(Nr−1), where Nr denotes a total number of electrode fingers 61a and 61b included in the electrode-finger region, and Dr denotes a center-to-center distance between an electrode finger located at one end in the acoustic wave propagation direction of the electrode-finger region and an electrode finger located at the other end thereof.

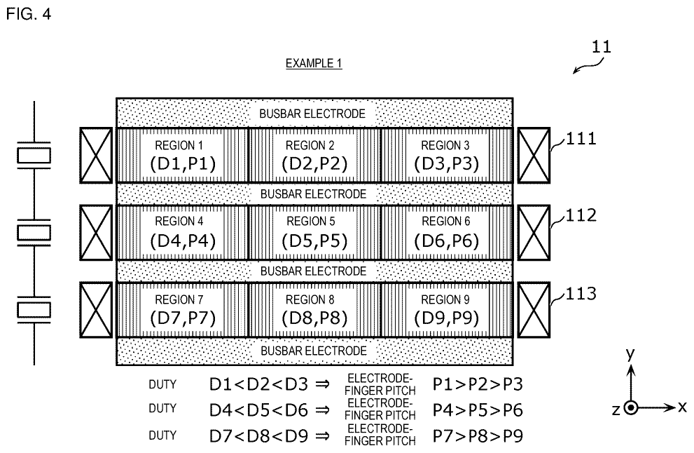

Next, the electrode configuration of the acoustic wave resonant circuit 11, which is a divided resonator group of the filter 10, will be described. FIG. 4 is a plan view illustrating an electrode configuration of the acoustic wave resonant circuit 11 according to Example 1 of an example embodiment of the present invention. FIG. 4 illustrates a planar layout of IDT electrodes and reflector electrodes provided on the piezoelectric substrates 50 of the series-arm resonators 111, 112, and 113 defining the acoustic wave resonant circuit 11 according to Example 1.

The IDT electrode of the series-arm resonator 111, the IDT electrode of the series-arm resonator 112, and the IDT electrode of the series-arm resonator 113 are arranged in this order in the y-axis direction with busbar electrodes interposed therebetween. Reflector electrodes of each of the series-arm resonators 111 to 113 are arranged at both ends of the IDT electrode in the x-axis direction.

The IDT electrode included in each of the series-arm resonators 111 to 113 is divided into multiple electrode-finger regions having different duties D, each electrode-finger region being defined as a region where two or more electrode fingers having an equal duty D are consecutively arranged.

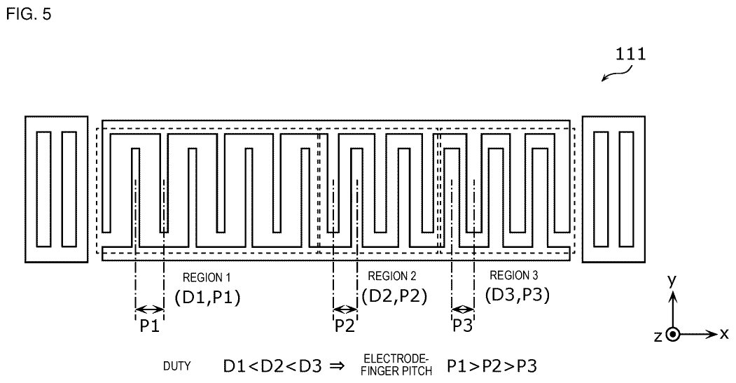

FIG. 5 is a plan view illustrating an electrode configuration of the series-arm resonator 111 defining a portion of the acoustic wave resonant circuit 11 according to Example 1. As illustrated in FIG. 5, the IDT electrode of the series-arm resonator 111 is specifically divided into region 1 (D1, P1) having duty D1 and electrode-finger pitch P1, region 2 (D2, P2) having duty D2 and electrode-finger pitch P2, and region 3 (D3, P3) having duty D3 and electrode-finger pitch P3. Duty D1 is different from duty D2. Duty D2 is different from duty D3. Note that duty D1 and duty D3 may be equal.

Additionally, as illustrated in FIG. 4, the IDT electrode of the series-arm resonator 112 is divided into region 1 (D4, P4) having duty D4 and electrode-finger pitch P4, region 5 (D5, P5) having duty D5 and electrode-finger pitch P5, and region 6 (D6, P6) having duty D6 and electrode-finger pitch P6. Duty D4 is different from duty D5. Duty D5 is different from duty D6. Note that duty D4 and duty D6 may be equal.

Furthermore, as illustrated in FIG. 4, the IDT electrode of the series-arm resonator 113 is divided into region 7 (D7, P7) having duty D7 and electrode-finger pitch P7, region 8 (D8, P8) having duty D8 and electrode-finger pitch P8, and region 9 (D9, P9) having duty D9 and electrode-finger pitch P9. Duty D7 is different from duty D8. Duty D8 is different from duty D9. Note that duty D7 and duty D9 may be equal.

In this example, the duties are in the order D1<D2<D3, and the electrode-finger pitches are in the order P1>P2>P3. Also, the duties are in the order D4<D5<D6, and the electrode-finger pitches are in the order P4>P5>P6. Furthermore, the duties are in the order D7<D8<D9, and the electrode-finger pitches are in the order P7>P8>P9.

That is, when the multiple electrode-finger regions (region 1, region 2, and region 3) of the IDT electrode of the series-arm resonator 111 are compared, the electrode-finger pitch decreases as the duty D increases.

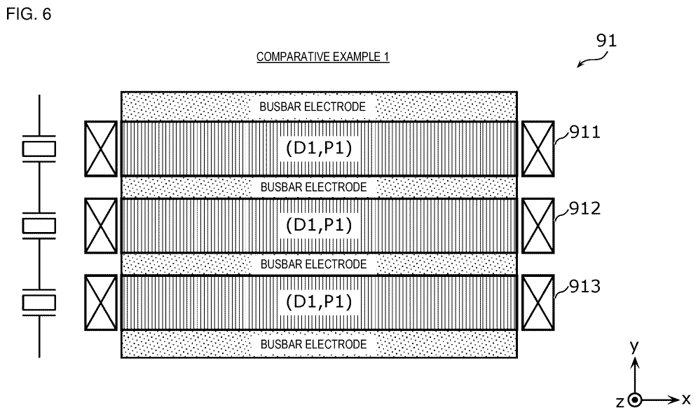

FIG. 6 is a plan view illustrating an electrode configuration of an acoustic wave resonant circuit 91 according to Comparative Example 1. The acoustic wave resonant circuit 91 illustrated in FIG. 6 defines a portion of a filter 500 according to Comparative Example 1. As compared with the filter 10 according to Example 1, the filter 500 according to Comparative Example 1 replaces the acoustic wave resonant circuit 11 with the acoustic wave resonant circuit 91, and the other circuit configurations are the same or substantially the same as those of the filter 10 according to Example 1.

As illustrated in FIG. 6, the acoustic wave resonant circuit 91 according to Comparative Example 1 includes series-arm resonators 911, 912, and 913 connected in series with one another. The IDT electrode of the series-arm resonator 911, the IDT electrode of the series-arm resonator 912, and the IDT electrode of the series-arm resonator 913 are arranged in this order in the y-axis direction with busbar electrodes interposed therebetween. Reflector electrodes of the series-arm resonators 911 to 913 are arranged at both ends of the IDT electrodes in the x-axis direction. The IDT electrode of each of the series-arm resonators 911 to 913 only includes one electrode-finger region (D1, P1) where two or more electrode fingers having an equal duty D are consecutively arranged.

Table 1 indicates electrode parameters of the acoustic wave resonant circuit 11 according to Example 1. Table 2 indicates electrode parameters of the acoustic wave resonant circuit 91 according to Comparative Example 1.

TABLE 1
Acoustic wave resonant circuit 11 (Example 1)

| | | Region 1 | Region 2 | Region 3 |
|---|---|---|---|---|
| Series-arm | Duty D | 0.46 | 0.47 | 0.48 |
| resonator 111 | Wavelength λ (μm) | 1.6584 | 1.6570 | 1.6557 |
| | Number of electrode | 206 | 205 | 206 |
| | fingers | | | |
| | Overlap width (μm) | 29.31 | ← | ← |
| | | Region 4 | Region 6 | Region 6 |
| Series-arm | Duty D | 0.49 | 0.50 | 0.51 |
| resonator 112 | Wavelength λ (μm) | 1.6546 | 1.6535 | 1.6525 |
| | Number of electrode | 206 | 205 | 206 |
| | fingers | | | |
| | Overlap width (μm) | 29.31 | ← | ← |
| | | Region 7 | Region 8 | Region 9 |
| Series-arm | Duty D | 0.52 | 0.53 | 0.54 |
| resonator 113 | Wavelength λ (μm) | 1.6516 | 1.6508 | 1.6502 |
| | Number of electrode | 206 | 205 | 206 |
| | fingers | | | |
| | Overlap width (μm) | 29.31 | ← | ← |

TABLE 2
Acoustic wave resonant circuit 91 (Comparative Example 1)

| | | Region 1 |
|---|---|---|
| Series-arm | Duty D | 0.50 |
| resonator 911 | Wavelength λ (μm) | 1.6535 |
| | Number of electrode fingers | 617 |
| | Overlap width (μm) | 29.31 |
| Series-arm | Duty D | 0.50 |
| resonator 912 | Wavelength λ (μm) | 1.6535 |
| | Number of electrode fingers | 617 |
| | Overlap width (μm) | 29.31 |
| Series-arm | Duty D | 0.50 |
| resonator 913 | Wavelength λ (μm) | 1.6535 |
| | Number of electrode fingers | 617 |
| | Overlap width (μm) | 29.31 |

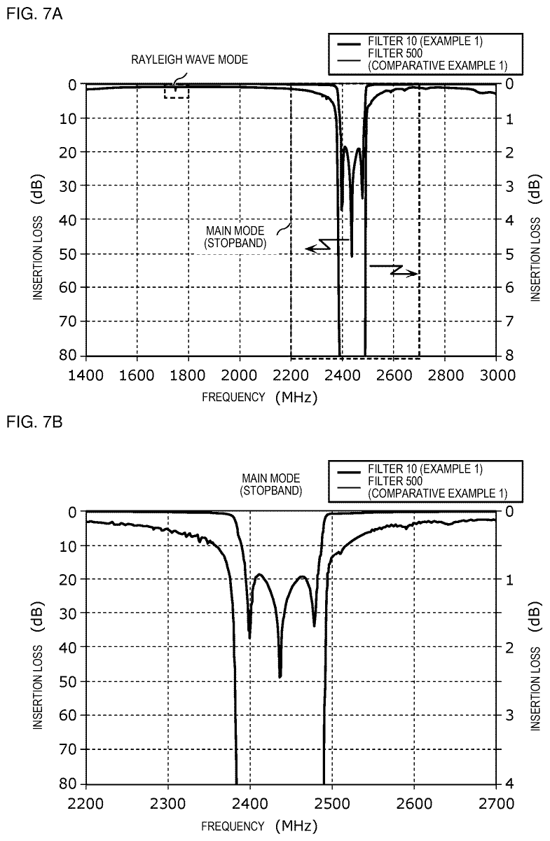

Next, the transmission characteristics of the filter 10 according to Example 1 and the filter 500 according to Comparative Example 1 will be described. FIG. 7A is a graph representing the transmission characteristics of the filters according to Example 1 and Comparative Example 1. As illustrated in FIG. 7A, in both of the filter 10 and the filter 500, a stopband of a notch filter due to a main mode is provided. FIG. 7B is a graph representing the transmission characteristics in the vicinity of the stopband of the filters according to Example 1 and Comparative Example 1. As illustrated in FIG. 7B, the transmission characteristics in the vicinity of the stopband are the same or approximately the same between the filters 10 and 500.

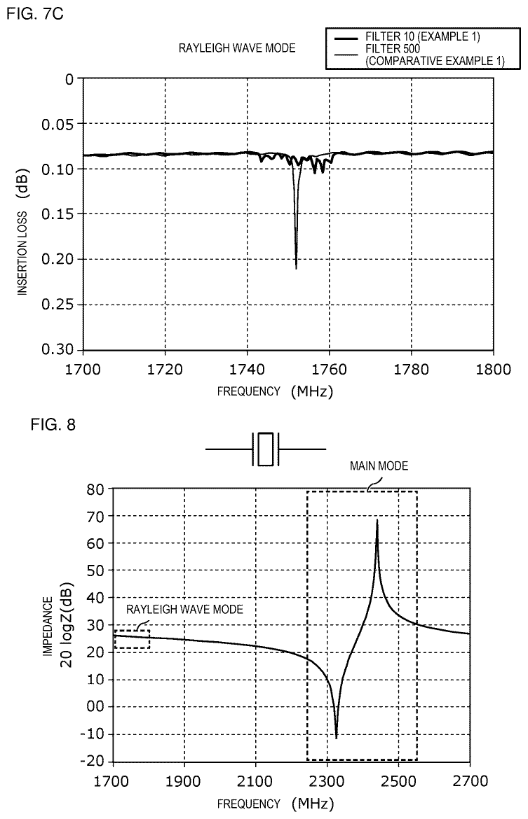

FIG. 7C is a graph representing the transmission characteristics in the vicinity of a frequency band in which a Rayleigh wave mode is generated, of the filters according to Example 1 and Comparative Example 1. In the filter 500 according to Comparative Example 1, ripples due to the Rayleigh wave mode occur in a frequency band at approximately 0.7 times the frequency of the main mode. In contrast, in the filter 10 according to Example 1, ripples due to the Rayleigh wave mode is reduced or prevented as compared with the filter 500 according to Comparative Example 1. In the filter 10 according to Example 1, factors by which the Rayleigh wave rippled are reduced or prevented will be described using FIGS. 8 to 10B.

FIG. 8 is a graph representing the resonance characteristics of an acoustic wave resonator. FIG. 8 indicates resonance characteristics of a single acoustic wave resonator including an IDT electrode in which the duty D is uniform, including the main mode including a resonance point and an anti-resonance point, and the Rayleigh wave mode appearing on the lower frequency side thereof.

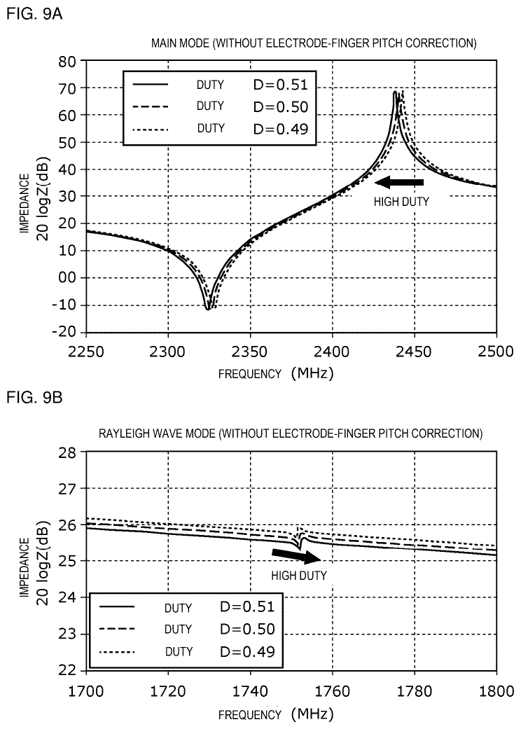

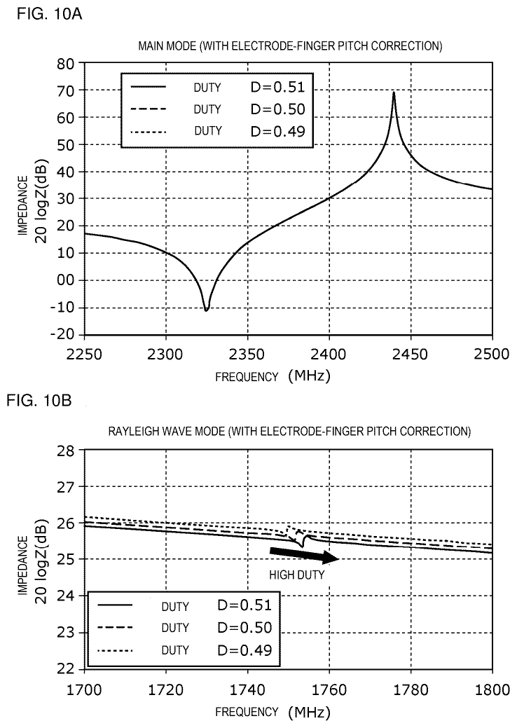

FIG. 9A is a graph representing resonance characteristics of the main mode when the duty D of the acoustic wave resonator is varied. FIG. 9B is a graph representing resonance characteristics of the Rayleigh wave mode when the duty D of the acoustic wave resonator is varied.

As indicated in FIG. 9A, as the duty D is increased from about 0.49 to about 0.51 in the acoustic wave resonator including the IDT electrode with the uniform duty D, the resonant frequency and the anti-resonant frequency of the main mode shift to lower frequencies. In contrast, as indicated in FIG. 9B, as the duty D is increased from about 0.49 to about 0.51 in the acoustic wave resonator having the IDT electrode with the unique duty D, the resonant frequency and the anti-resonant frequency of the Rayleigh wave mode shift to higher frequencies.

By utilizing the fact that the main mode and the Rayleigh wave mode shift in opposite directions in frequency due to variations of the duty D, it is possible to shift the frequency of the Rayleigh wave mode significantly without shifting the frequency of the main mode by adjusting the electrode-finger pitch, even when the duty D is varied.

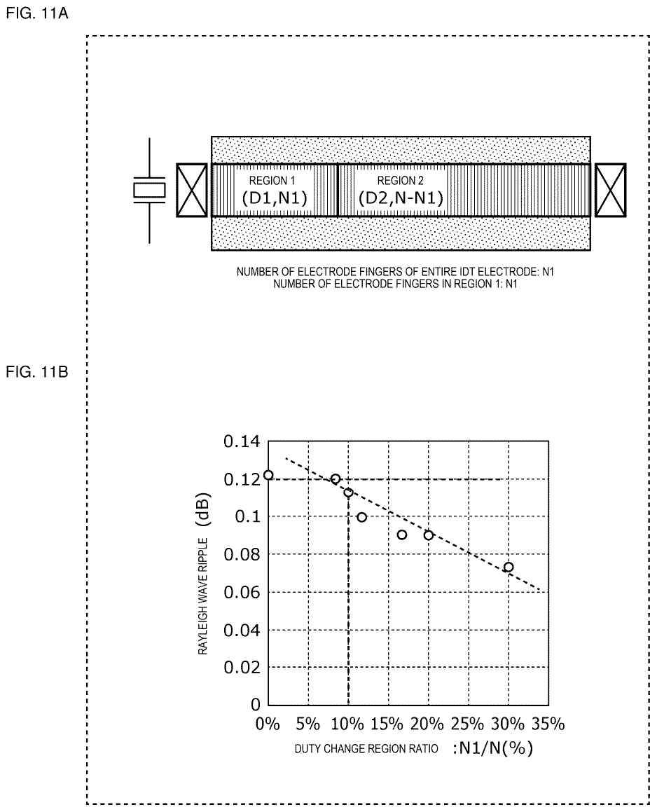

FIG. 10A is graph a representing resonance characteristics of the main mode when the electrode-finger pitch is corrected in response to variations in the duty D of the acoustic wave resonator. Specifically, the electrode-finger pitch is reduced as the duty D is increased. Accordingly, as illustrated in FIG. 10A, even when the duty D is varied, the resonant frequency and the anti-resonant frequency of the main mode do not vary.

FIG. 10B is a graph representing resonance characteristics of the Rayleigh wave mode when the electrode-finger pitch is corrected in response to variations in the duty D of the acoustic wave resonator. As indicated in FIG. 9B, as the duty D is increased, the resonant frequency and the anti-resonant frequency of the Rayleigh wave mode shift to higher frequencies. In contrast, as the electrode-finger pitch is decreased, the resonant frequency and the anti-resonant frequency of the Rayleigh wave mode shift to higher frequencies. Therefore, when the duty D is increased and the electrode-finger pitch is decreased, the resonant frequency and the anti-resonant frequency of the Rayleigh wave mode greatly shift to higher frequencies. In other words, by decreasing the electrode-finger pitch as the duty D of the acoustic wave resonator is increased, it is possible to disperse the resonant frequency of the Rayleigh wave mode without deteriorating the resonance characteristics of the main mode.

There has been proposed a configuration to adjust the duty D and the electrode-finger pitch among the multiple acoustic wave resonators divided in series by utilizing the resonance characteristics indicated in FIGS. 10A and 10B. However, in the case of the above configuration, it is necessary to increase the number of series-connected resonator sections of the acoustic wave resonators in order to reduce ripples due to the Rayleigh wave mode. In this case, the area to arrange the series-divided acoustic wave resonators increases, and the filter becomes larger.

In contrast, in the filter 10 according to the present example embodiment, the IDT electrode of each of the series-arm resonators 111 to 113 is divided into three regions including different duties D. As indicated in Table 1, in these three regions, the electrode finger pitch (wavelength λ in Table 1) is decreased as the duty D is increased.

According to this configuration, the resonant frequency and the anti-resonant frequency of the main mode generated in different electrode-finger regions within one IDT electrode can be respectively made to coincide with each other, while the resonant frequency and the anti-resonant frequency of the Rayleigh wave mode generated in these different electrode-finger regions can be respectively dispersed. As a result, a single divided resonator makes it possible to reduce or prevent ripples due to the Rayleigh wave mode without deteriorating the resonance characteristics of the main mode. It is thus possible to provide the compact filter 10 with reduced ripples due to the Rayleigh wave mode without increasing the number of series-connected resonator sections of the acoustic wave resonant circuit 11.

In the filter 10 according to the present example embodiment, the duty is also made different among the three series-divided series-arm resonators 111 to 113. From Table 1, for example, the average duty of the series-arm resonator 111 is about 0.47, the average duty of the series-arm resonator 112 is about 0.50, and the average duty of the series-arm resonator 113 is about 0.53.

According to this configuration, since the frequencies of the Rayleigh wave modes generated in the respective series-arm resonators 111 to 113 can be dispersed, Rayleigh wave ripples of the filter 10 can be further improved.

Next, the number of electrode fingers in each electrode-finger region required to effectively reduce ripples due to the Rayleigh wave mode will be described. FIGS. 11A and 11B include graphs representing variations in Rayleigh wave ripples when the number of electrode fingers in each region of the acoustic wave resonator is varied. FIG. 11B illustrates Rayleigh wave ripples of the filter 10 when the acoustic wave resonant circuit 11 of the filter 10 is replaced with one acoustic wave resonator illustrated in FIG. 11A. As illustrated in FIG. 11A, it is assumed that the IDT electrode of the acoustic wave resonator includes region 1 with duty D1 and the number of electrode fingers N1, and region 2 with duty D2 and the number of electrode fingers (N-N1). The number of electrode fingers N is the total number of electrode fingers of the IDT electrode. FIG. 11B indicates a relationship between a duty variation region ratio (N1/N), which is a ratio of the number of electrode fingers in region 1 to the total number of electrode fingers, and Rayleigh wave ripples (dB) generated in the acoustic wave resonator.

Table 3 indicates the duty variation region ratio, and each region's electrode parameters.

TABLE 3
Acoustic wave resonator

| | Region 1 | | | | Region 2 | | | |
|---|---|---|---|---|---|---|---|---|
| | Number | | | | Number | | | |
| Duty change | of | | | Overlap | of | | | Overlap |
| region ratio | electrode | | Wavelength | width | electrode | | Wavelength | width |
| N1/N (%) | fingers | Duty D | λ (μm) | (μm) | fingers | Duty D | λ (μm) | (μm) |
| 0 | 0 | 0.49 | 1.6548 | 20.1 | 600 | 0.50 | 1.6535 | 20.1 |
| 8 | 50 | ↑ | ↑ | ↑ | 550 | ↑ | ↑ | ↑ |
| 10 | 60 | ↑ | ↑ | ↑ | 540 | ↑ | ↑ | ↑ |
| 12 | 70 | ↑ | ↑ | ↑ | 530 | ↑ | ↑ | ↑ |
| 17 | 100 | ↑ | ↑ | ↑ | 500 | ↑ | ↑ | ↑ |
| 20 | 120 | ↑ | ↑ | ↑ | 480 | ↑ | ↑ | ↑ |
| 30 | 180 | ↑ | ↑ | ↑ | 420 | ↑ | ↑ | ↑ |
| 50 | 300 | ↑ | ↑ | ↑ | 300 | ↑ | ↑ | ↑ |

As indicated in FIG. 11B, when the duty variation region ratio (N1/N) of region 1 is about 8% or less, Rayleigh wave ripples are not reduced, as compared with a case where the IDT electrode includes only one electrode-finger region (duty variation region ratio=0%). In contrast, when the duty variation region ratio (N1/N) of region 1 is about 10% or more, it is clear that Rayleigh wave ripples can be reduced.

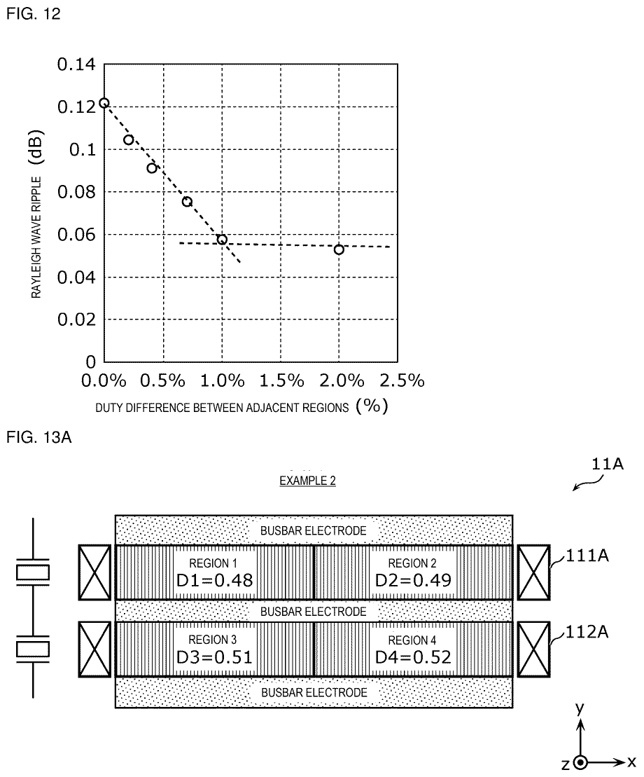

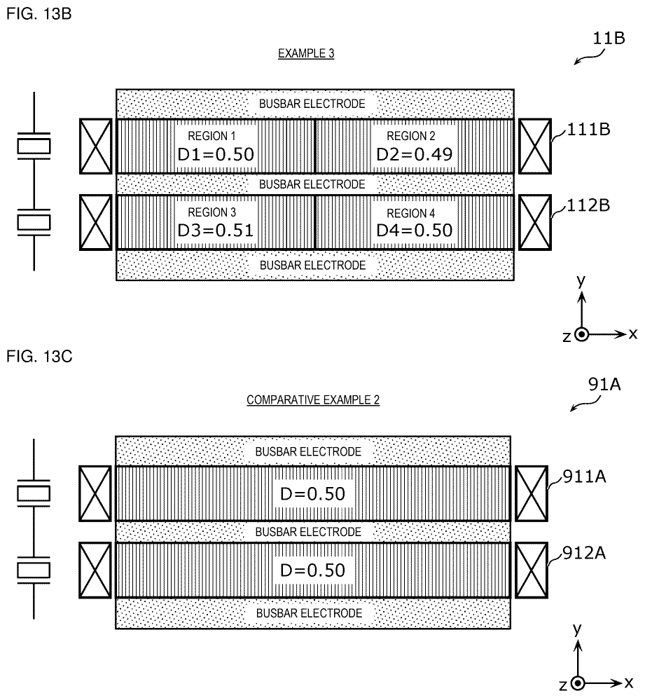

Next, a duty difference between regions to stably reduce ripples due to the Rayleigh wave mode will be described. FIG. 12 is a graph representing variations in Rayleigh wave ripples when the difference in duty D between regions of the acoustic wave resonator is varied. FIG. 12 illustrates Rayleigh wave ripples of the filter 10 when the acoustic wave resonant circuit 11 of the filter 10 is replaced with one acoustic wave resonator indicated in Table 4. More specifically, FIG. 12 indicates a relationship between a duty difference between regions of the acoustic wave resonator including an IDT electrode including region 1 with duty D1 and region 2 with duty D2, and Rayleigh wave ripple (dB) of the filter 10.

Table 4 indicates the duty difference between regions, and each region's electrode parameters.

TABLE 4
Acoustic wave resonator

| Duty | Region 1 | | | | Region 2 | | | |
|---|---|---|---|---|---|---|---|---|
| difference | | | Number | | | | Number | |
| between | | | of | Overlap | | | of | \|Overlap |
| regions | | Wavelength | electrode | width | | Wavelength | electrode | width |
| (%) | Duty D | λ (μm) | fingers | (μm) | Duty D | λ (μm) | fingers | (μm) |
| 0 | 0.500 | 1.6535 | 300 | 20.1 | 0.500 | 1.6535 | 300 | 20.1 |
| 0.2 | 0.499 | 1.6539 | ↑ | ↑ | ↑ | ↑ | ↑ | ↑ |
| 0.4 | 0.498 | 1.6540 | ↑ | ↑ | ↑ | ↑ | ↑ | ↑ |
| 0.7 | 0.497 | 1.6541 | ↑ | ↑ | ↑ | ↑ | ↑ | ↑ |
| 1.0 | 0.495 | 1.6543 | ↑ | ↑ | ↑ | ↑ | ↑ | ↑ |
| 2.0 | 0.490 | 1.6548 | ↑ | ↑ | ↑ | ↑ | ↑ | ↑ |

As indicated in FIG. 12, when the duty difference between regions is small, the frequencies at which the Rayleigh wave mode occurs due to the respective regions become closer to each other, and the dispersion effect is reduced. On the other hand, as the duty difference between regions increases, Rayleigh wave ripples are reduced, and when the duty difference between regions is about 1.0% or more, the reduction in Rayleigh wave ripples is saturated. According to this configuration, it is preferable to have a duty difference between regions of, for example, about 1.0% or more in order to achieve a large and stable reduction in Rayleigh wave ripples.

In the acoustic wave resonant circuit 11 according to the present example embodiment, it is preferable that the distance between the IDT electrode and the reflector electrode of the series-arm resonator 111 (hereinafter referred to as I-R gap) is different from the distance between adjacent electrode fingers (electrode-finger pitch) in the IDT electrode. It is also preferable that the distance between adjacent electrode fingers of the reflector electrode (hereinafter referred to as the reflector-electrode-finger pitch) is different from the electrode-finger pitch of the IDT electrode. In the present example, for example, by making the I-R gap smaller than the electrode-finger pitch of the IDT electrode and the reflector-electrode-finger pitch smaller than the electrode-finger pitch of the IDT electrode, vertical mode ripples can be reduced.

Accordingly, Rayleigh wave ripples and vertical mode ripples can be reduced.

In the present example embodiment, the first acoustic wave resonant circuit (acoustic wave resonant circuit 11) having a configuration in which multiple divided resonators, each including multiple electrode-finger regions with different duties, are connected in series, is most closely connected to the common terminal 100 among the multiple acoustic wave resonant circuits constituting the filter 10.

Accordingly, return loss at a frequency at which a Rayleigh wave spurious response occurs when the filter 10 is viewed from the common terminal 100 can be effectively reduced. It is thus possible to reduce prevent, at the above-described occurrence frequency, deterioration of the transmission characteristics of the filter 20 connected to the common terminal 100.

The first acoustic wave resonant circuit need not be applied to the acoustic wave resonant circuit that is most closely connected to the common terminal 100, and may instead be applied to at least one of the multiple acoustic wave resonant circuits of the filter 10. Even in this case, it is possible to provide the compact filter 10 with reduced ripples due to the Rayleigh wave mode without increasing the number of series-connected resonator sections of the first acoustic wave resonant circuit.

FIG. 13A is a plan view illustrating an electrode configuration of an acoustic wave resonant circuit 11A according to Example 2 of an example embodiment of the present invention. The acoustic wave resonant circuit 11A according to the present example includes series-arm resonators 111A and 112A connected in series with each other. As compared with the acoustic wave resonant circuit 11 according to Example 1, the acoustic wave resonant circuit 11A according to the present example differs in the number of series-connected acoustic wave resonators and the duty configuration of the electrode-finger regions. The filter according to the present example differs from the filter 10 according to Example 1 only in that the acoustic wave resonant circuit 11 is replaced with the acoustic wave resonant circuit 11A. Table 5 indicates electrode parameters of the acoustic wave resonant circuit 11A according to Example 2.

TABLE 5
Acoustic wave resonant circuit 11A (Example 2)

| | | Region 1 | Region 2 |
|---|---|---|---|
| Series-arm | Duty D | 0.48 | 0.49 |
| resonator 111A | Wavelength λ (μm) | 1.6559 | 1.6548 |
| | Number of electrode | 300 | ← |
| | fingers | | |
| | Overlap width (μm) | 20.1 | ← |
| | | Region 3 | Region 4 |
| Series-arm | Duty D | 0.51 | 0.52 |
| resonator 112A | Wavelength λ (μm) | 1.6528 | 1.6535 |
| | Number of electrode | 300 | ← |
| | fingers | | |
| | Overlap width (μm) | 20.1 | ← |

As indicated in FIG. 13A and Table 5, the series-arm resonator 111A includes two electrode-finger regions (region 1 and region 2), and the series-arm resonator 112A includes two electrode-finger regions (region 3 and region 4). The duty D of region 1 is about 0.48, the duty D of region 2 is about 0.49, the duty D of region 3 is about 0.51, and the duty D of region 4 is about 0.52. In other words, the duties D of all of the electrode-finger regions of the acoustic wave resonant circuit 11A are different.

FIG. 13B is a plan view illustrating an electrode configuration of an acoustic wave resonant circuit 11B according to Example 3 of an example embodiment of the present invention. The acoustic wave resonant circuit 11B according to the present example includes series-arm resonators 111B and 112B connected in series with each other. As compared with the acoustic wave resonant circuit 11 according to Example 1, the acoustic wave resonant circuit 11B according to the present example differs in the number of series-connected acoustic wave resonators and the duty configuration of the electrode-finger regions. The filter according to the present example differs from the filter 10 according to Example 1 only in that the acoustic wave resonant circuit 11 is replaced with the acoustic wave resonant circuit 11B. Table 6 indicates electrode parameters of the acoustic wave resonant circuit 11B according to Example 3.

TABLE 6
Acoustic wave resonant circuit 11B (Example 3)

| | | Region 1 | Region 2 |
|---|---|---|---|
| Series-arm | Duty D | 0.50 | 0.49 |
| resonator 111B | Wavelength λ (μm) | 1.6538 | 1.6548 |
| | Number of electrode | 300 | ← |
| | fingers | | |
| | Overlap width (μm) | 20.1 | ← |
| | | Region 3 | Region 4 |
| Series-arm | Duty D | 0.51 | 0.50 |
| resonator 112B | Wavelength λ (μm) | 1.6528 | 1.6538 |
| | Number of electrode | 300 | ← |
| | fingers | | |
| | Overlap width (μm) | 20.1 | ← |

As indicated in FIG. 13B and Table 6, the series-arm resonator 111B includes two electrode-finger regions (region 1 and region 2), and the series-arm resonator 112B includes two electrode-finger regions (region 3 and region 4). The duty D of region 1 is about 0.50, the duty D of region 2 is about 0.49, the duty D of region 3 is about 0.51, and the duty D of region 4 is about 0.50. The duty D of region 1 and the duty D of region 2 of the series-arm resonator 111B are different, and the duty D of region 3 and the duty D of region 4 of the series-arm resonator 112B are different. Also, the duty D of region 1 and the duty D of region 4 are equal.

FIG. 13C is a plan view illustrating an electrode configuration of an acoustic wave resonant circuit 91A according to Comparative Example 2. The acoustic wave resonant circuit 91A according to the present comparative example includes series-arm resonators 911A and 912A connected in series with each other. As compared with the acoustic wave resonant circuit 91 according to Comparative Example 1, the acoustic wave resonant circuit 91A according to the present comparative example differs in the number of series-connected acoustic wave resonators. The filter according to the present comparative example differs from the filter 500 according to Comparative Example 1 only in that the acoustic wave resonant circuit 91 is replaced with the acoustic wave resonant circuit 91A. Table 7 indicates electrode parameters of the acoustic wave resonant circuit 91A according to Comparative Example 2.

TABLE 7
Acoustic wave resonant circuit 91A (Comparative Example 2)

| | | Region 1 |
|---|---|---|
| Series-arm | Duty D | 0.50 |
| resonator 911A | Wavelength λ (μm) | 1.6538 |
| | Number of electrode fingers | 600 |
| | Overlap width (μm) | 20.1 |
| Series-arm | Duty D | 0.50 |
| resonator 912A | Wavelength λ (μm) | 1.6538 |
| | Number of electrode fingers | 600 |
| | Overlap width (μm) | 20.1 |

As indicated in FIG. 13C and Table 7, the series-arm resonator 911A includes one electrode-finger region (region 1), and the series-arm resonator 912A includes one electrode-finger region (region 2). The duty D of region 1 is about 0.50, and the duty D of region 2 is about 0.50.

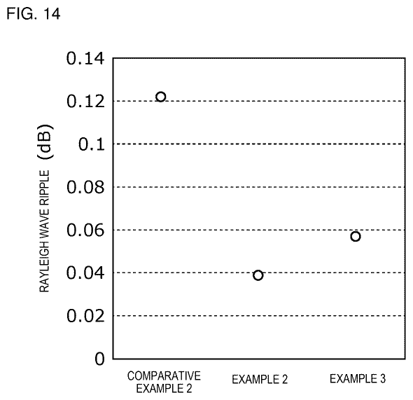

FIG. 14 is a graph representing the Rayleigh wave ripples of the filters according to Example 2, Example 3, and Comparative Example 2. As indicated in FIG. 14, the filters according to Examples 2 and 3 have reduced Rayleigh wave ripples as compared with the filter according to Comparative Example 2.

This is because, in the filters according to Example 2 and Example 3, the resonant frequency and the anti-resonant frequency of the main mode generated in different electrode-finger regions within a single IDT electrode are respectively made to coincide with each other, whereas the resonant frequency and the anti-resonant frequency of the Rayleigh wave mode generated in these different electrode-finger regions are respectively dispersed.

Furthermore, the filter according to Example 2 has reduced Rayleigh wave ripples as compared with the filter according to Example 3. This is because, in the acoustic wave resonant circuit 11A according to Example 2, the duties D of all of the electrode-finger regions (regions 1 to 4) are different, and therefore the dispersion effect of the resonant frequency and the anti-resonant frequency of the Rayleigh wave mode generated in the four electrode-finger regions is maximized.

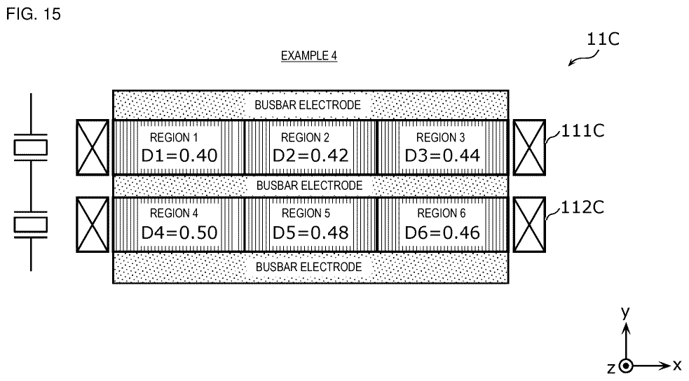

FIG. 15 is a plan view illustrating an electrode configuration of an acoustic wave resonant circuit 11C according to Example 4 of an example embodiment of the present invention. The acoustic wave resonant circuit 11C according to the present example includes series-arm resonators 111C and 112C connected in series with each other. As compared with the acoustic wave resonant circuit 11 according to Example 1, the acoustic wave resonant circuit 11C according to the present example differs in the number of series-connected acoustic wave resonators and the duty configuration of the electrode-finger regions. The filter according to the present example differs from the filter 10 according to Example 1 only in that the acoustic wave resonant circuit 11 is replaced with the acoustic wave resonant circuit 11C.

As illustrated in FIG. 15, the series-arm resonator 111C includes three electrode-finger regions (regions 1, 2, and 3), and the series-arm resonator 112B includes three electrode-finger regions (regions 4, 5, and 6). The duty D of region 1 is about 0.40, the duty D of region 2 is about 0.42, and the duty D of region 3 is about 0.44. Also, the duty D of region 4 is about 0.50, the duty D of region 5 is about 0.48, and the duty D of region 6 is about 0.46.

Here, the series-arm resonator 111C is an example of a first acoustic wave resonator, and the series-arm resonator 112C is an example of a second acoustic wave resonator. The IDT electrode of the series-arm resonator 111C and the IDT electrode of the series-arm resonator 112C are arranged adjacent to each other in a first direction (y-axis direction), which is the electrode finger extension direction, on the main surface of the piezoelectric substrate 50. Region 3, which is the electrode-finger region with the maximum duty D among regions 1 to 3 of the series-arm resonator 111C, and region 4, which is the electrode-finger region with the maximum duty D among regions 4 to 6 of the series-arm resonator 112C, do not overlap in the above-described extension direction (y-axis direction).

Generally, as the duty D increases, the area occupancy of the electrode fingers increases, and the heat generation area ratio increases. Accordingly, as the duty D increases, the electric power handling capability of the electrode-finger region decreases. In contrast, according to the acoustic wave resonant circuit 11C according to the present example, in the adjacent series-arm resonators 111C and 112C, region 3 and region 4 with the maximum duties D do not overlap in the above-described extension direction (y-axis direction). Thus, the heat generation of the acoustic wave resonant circuit 11C can be dispersed, and the electric power handling capability of the acoustic wave resonant circuit 11C can be improved.

Additionally, regions 1 to 3 of the series-arm resonator 111C are arranged in descending order of duty in a second direction (x-axis negative direction) parallel or substantially parallel to the main surface of the piezoelectric substrate 50 and perpendicular or substantially perpendicular to the first direction (y-axis direction). In contrast, regions 4 to 6 of the series-arm resonator 112C are arranged in descending order of duty in a third direction (x-axis positive direction) which is opposite to the second direction.

According to this configuration, by reversing the direction in which the duty D of the electrode-finger regions increases/decreases between the adjacent series-arm resonators 111C and 112C, the heat generation of the acoustic wave resonant circuit 11C can be dispersed, and the electric power handling capability of the acoustic wave resonant circuit 11C can be improved. Thus, according to the filter according to the present example, Rayleigh wave ripples can be reduced, and the electric power handling capability can be improved.

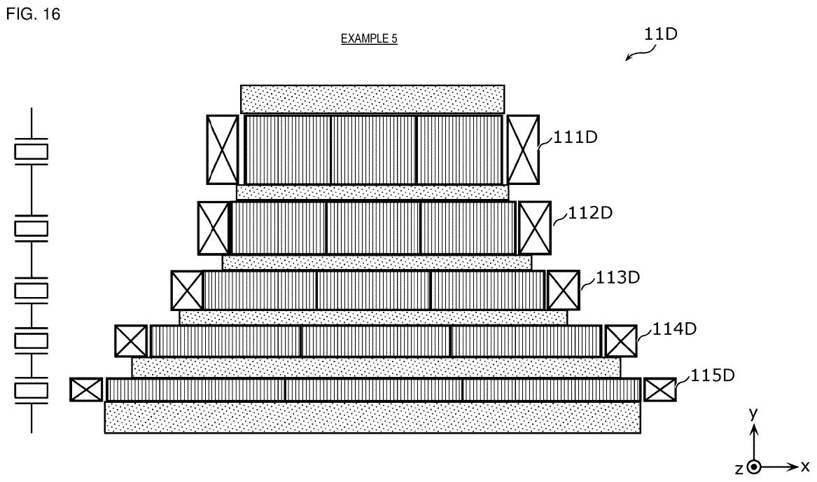

FIG. 16 is a plan view illustrating an electrode configuration of an acoustic wave resonant circuit 11D according to Example 5 of an example embodiment of the present invention.

The acoustic wave resonant circuit 11D according to the present example includes series-arm resonators 111D, 112D, 113D, 114D, and 115D connected in series with one another. As compared with the acoustic wave resonant circuit 11 according to Example 1, the acoustic wave resonant circuit 11D according to the present example differs in the number of series-connected acoustic wave resonators and the shape of each IDT electrode. The filter according to the present example differs from the filter 10 according to Example 1 only in that the acoustic wave resonant circuit 11 is replaced with the acoustic wave resonant circuit 11D. Table 8 indicates electrode parameters of the acoustic wave resonant circuit 11D according to Example 5.

TABLE 8
Acoustic wave resonant circuit 11D (Example 5)

| | | Region 1 | Region 2 | Region 3 |
|---|---|---|---|---|
| Series-arm | Duty D | 0.465 | 0.470 | 0.480 |
| resonator 111D | Wavelength λ (μm) | 1.6000 | 1.5995 | 1.5990 |
| | Number of electrode | 109 | ← | ← |
| | fingers | | | |
| | Overlap width (μm) | 17.63 | ← | ← |
| | | Region 4 | Region 5 | Region 6 |
| Series-arm | Duty D | 0.480 | 0.490 | 0.490 |
| resonator 112D | Wavelength λ (μm) | 1.5985 | 1.5980 | 1.5974 |
| | Number of electrode | 114 | 115 | 114 |
| | fingers | | | |
| | Overlap width (μm) | 16.80 | ← | ← |
| | | Region 7 | Region 8 | Region 9 |
| Series-arm | Duty D | 0.495 | 0.500 | 0.510 |
| resonator 113D | Wavelength λ (μm) | 1.5969 | 1.5964 | 1.5959 |
| | Number of electrode | 120 | 121 | 120 |
| | fingers | | | |
| | Overlap width (μm) | 15.96 | ← | ← |
| | | Region 10 | Region 11 | Region 12 |
| Series-arm | Duty D | 0.510 | 0.520 | 0.520 |
| resonator 114D | Wavelength λ (μm) | 1.5954 | 1.5949 | 1.5943 |
| | Number of electrode | 126 | 127 | 126 |
| | fingers | | | |
| | Overlap width (μm) | 15.20 | ← | ← |
| | | Region 13 | Region 14 | Region 15 |
| Series-arm | Duty D | 0.525 | 0.530 | 0.540 |
| resonator 115D | Wavelength λ (μm) | 1.5938 | 1.5933 | 1.5928 |
| | Number of electrode | 134 | 133 | 134 |
| | fingers | | | |
| | Overlap width (μm) | 14.37 | ← | ← |

As illustrated in Table 8, each of the series-arm resonators 111D to 115D includes multiple electrode-finger regions with different duties D, and the electrode-finger pitch decreases as the duty D increases.

Furthermore, the aspect ratio, which is the ratio of the overlap width of the IDT electrode (longitudinal dimension) to the product of the number of electrode fingers and the wavelength λ (transverse dimension), differs among the series-arm resonators. The product of the number of electrode fingers and the wavelength λ corresponds to the length of the IDT electrode in a direction (x-axis direction) perpendicular or substantially perpendicular to the electrode fingers.

In each acoustic wave resonator including an IDT electrode provided on the piezoelectric substrate 50, in addition to Rayleigh wave ripples, transverse mode ripples may be generated between the resonant frequency and the anti-resonant frequency of the main mode. The frequency at which transverse mode ripples occurs, and the size thereof depend on the aspect ratio of the IDT electrode.

In contrast, in the acoustic wave resonant circuit 11D according to the present example, since the aspect ratio is made different among the series-connected series-arm resonators 111D to 115D, transverse mode ripples can be dispersed. It is thus possible to provide a filter with reduced Rayleigh wave ripples and reduced transverse mode ripples.

Although the aspect ratio is different among all of the series-arm resonators 111D to 115D, it is sufficient that the aspect ratio is different among two series-arm resonators among the series-arm resonators 111D to 115D of the acoustic wave resonant circuit 11D. Accordingly, the filter according to the present example can reduce transverse mode ripples, as compared with a filter in which all of the series-arm resonators of the acoustic wave resonant circuit have the same or substantially the same aspect ratio.

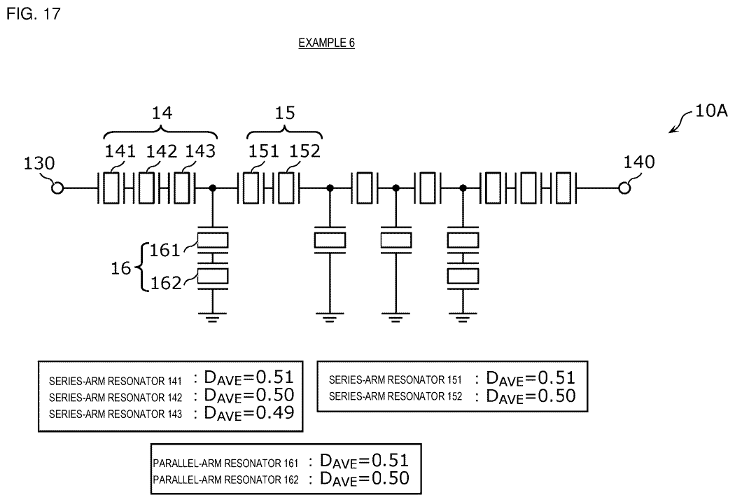

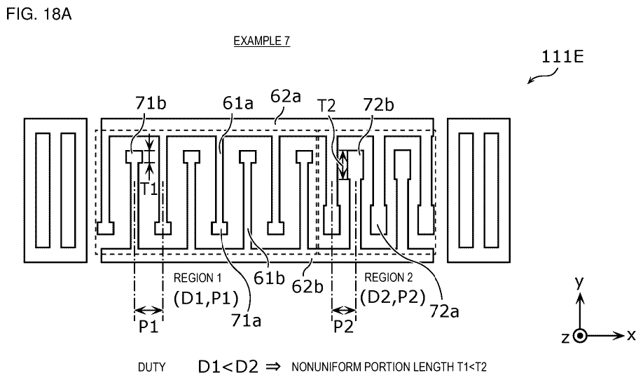

FIG. 17 is a circuit configuration diagram of a filter 10A according to Example 6 of an example embodiment of the present invention. The filter 10A is an example of an acoustic wave device and is provided instead of the filter 10 in the multiplexer 1 illustrated in FIG. 1. The filter 10A is connected to the common terminal 100, and, for example, is a band-pass filter having a passband.

The filter 10A includes multiple acoustic wave resonant circuits. Specifically, the filter 10A includes series-arm resonators 141, 142, 143, 151, and 152, parallel-arm resonators 161 and 162, and terminals 130 and 140. The terminal 130 is connected to the common terminal 100.

The series-arm resonators 141, 142, and 143 are examples of a first acoustic wave resonant circuit, and define an acoustic wave resonant circuit 14. The series-arm resonators 151 and 152 define an acoustic wave resonant circuit 15. The parallel-arm resonators 161 and 162 define an acoustic wave resonant circuit 16.

The series-arm resonators 141, 142, and 143 are acoustic wave resonators connected in series with one another between the terminals 130 and 140, and define a divided resonator group. The series-arm resonators 151 and 152 are acoustic wave resonators connected in series with each other between the terminals 130 and 140, and define a divided resonator group.

The parallel-arm resonators 161 and 162 are acoustic wave resonators connected in series with each other between a path connecting the acoustic wave resonant circuits 14 and 15 and ground, and define a divided resonator group.

Each of the series-arm resonators 141 to 143, 151, and 152, and the parallel-arm resonators 161 and 162 includes an IDT electrode disposed on a substrate having piezoelectric properties.

The circuit configuration of the filter 10A illustrated in FIG. 17 is an example of a band-pass filter, and it is sufficient that the number of acoustic wave resonant circuits is one or more in the series-arm path and one or more in the parallel-arm path.

Additionally, the number of acoustic wave resonators defining each divided resonator group is not limited to two or three, and may instead be four or more, for example.

Furthermore, an inductor may be connected between at least one of the parallel-arm resonators and ground.

The filter 10A is not limited to a ladder filter, and may instead be, for example, a filter including a longitudinally coupled resonator unit in which multiple acoustic wave resonators are arranged side by side in an acoustic wave propagation direction.

The IDT electrode included in each of the series-arm resonators 141, 142, 143, 151, and 152 and the parallel-arm resonators 161 and 162 is divided into multiple electrode-finger regions including different duties D. Additionally, the electrode-finger pitch is decreased as the duty D is increased in the multiple electrode-finger regions.

According to this configuration, the resonant frequency and the anti-resonant frequency of the main mode generated in different electrode-finger regions within one IDT electrode can be respectively made to coincide with each other, while the resonant frequency and the anti-resonant frequency of the Rayleigh wave mode generated in these different electrode-finger regions can be respectively dispersed. As a result, a single divided resonator including the above-described electrode-finger regions makes it possible to reduce or prevent ripples due to the Rayleigh wave mode without deteriorating the resonance characteristics of the main mode. It is thus possible to provide the compact filter 10A with reduced ripples due to the Rayleigh wave mode without increasing the number of series-connected resonator sections of the acoustic wave resonant circuit.

Here, an average duty D_{AVE} is defined in each of the series-arm resonators 141, 142, 143, 151, and 152, and the parallel-arm resonators 161 and 162. The average duty D_{AVE} refers to a value obtained by averaging the duties D of electrode-finger regions that define one acoustic wave resonator. When one acoustic wave resonator includes m electrode-finger regions (R1 to Rm), the number of electrode fingers in region k is nk, and the duty of region k is Dk, and the total number of electrode fingers of this acoustic wave resonator is N, the average duty D_{AVE} of this acoustic wave resonator is represented by equation 1:

$${D}_{AVE} = \frac{1}{N} {\sum }_{k = 1}^{m} nk \times Dk \qquad ( equation 1 )$$

In the filter 10A according to the present example, as illustrated in FIG. 17, for example, the average duty D_{AVE} of the series-arm resonator 141 is about 0.51, the average duty D_{AVE} Of the series-arm resonator 142 is about 0.50, and the average duty D_{AVE} of the series-arm resonator 143 is about 0.49. That is, the series-arm resonator 141 which is most closely connected to the common terminal 100 among the series-arm resonators 141 to 143 included in the acoustic wave resonant circuit 14 includes the largest average duty D_{AVE} among the series-arm resonators 141 to 143.

It is generally known that, in a filter including acoustic wave resonators, an acoustic wave resonator connected closer to the common terminal 100 has a greater influence on intermodulation distortion, and that intermodulation distortion is reduced or prevented as the duty increases.

According to the above-described configuration of the filter 10A according to the present example, among the series-arm resonators 141 to 143 included in the acoustic wave resonant circuit 14, the series-arm resonator 141 which is most closely connected to the common terminal 100 has the largest average duty D_{AVE}, and hence it can effectively suppress intermodulation distortion generated by the filter 10A.

The effect of reducing or preventing intermodulation distortion is not limited to a case where the acoustic wave resonant circuit 14 which is most closely connected to the common terminal 100 is configured to have the above-described average duty D_{AVE}. For example, among the series-arm resonators 151 (D_{AVE}=about 0.51) and 152 (D_{AVE}=about 0.50) of the acoustic wave resonant circuit 15, even if the series-arm resonator 151 which is most closely connected to the common terminal 100 has the largest average duty D_{AVE} of the series-arm resonators 151 and 152, intermodulation distortion generated by the filter 10A can be effectively reduced or prevented. Additionally, for example, among the parallel-arm resonators 161 (D_{AVE}=about 0.51) and 162 (D_{AVE}=about 0.50) of the acoustic wave resonant circuit 16, even if the parallel-arm resonator 161 which is most closely connected to the common terminal 100 has the largest average duty D_{AVE} of the parallel-arm resonators 161 and 162, intermodulation distortion generated by the filter 10A can be effectively reduced or prevented.

Next, an electrode configuration of the first acoustic wave resonant circuit including IDT electrodes with a piston structure will be described.

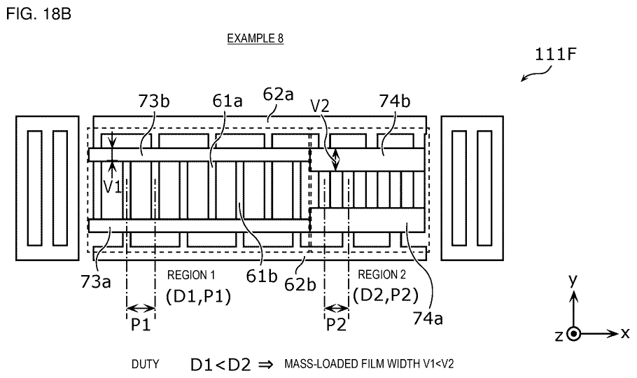

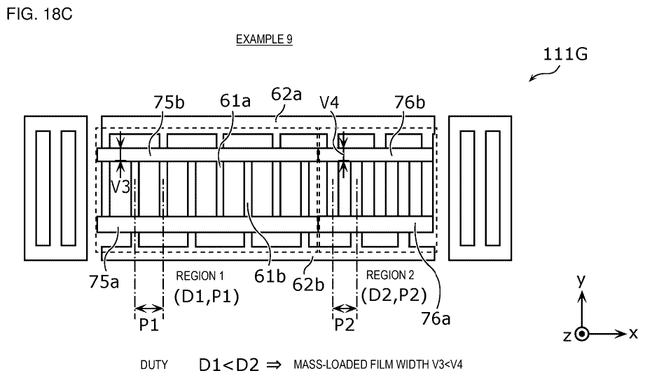

FIG. 18A is a plan view illustrating an electrode configuration of a series-arm resonator 111E defining a portion of an acoustic wave resonant circuit 11E according to Example 7 of an example embodiment of the present invention. The acoustic wave resonant circuit 11E according to the present example includes the series-arm resonators 111E and 112E connected in series with each other. As compared with the acoustic wave resonant circuit 11A according to Example 2, the acoustic wave resonant circuit 11E according to the present example differs in that each of the IDT electrodes of the series-arm resonators 111E and 112E has a 2D piston structure. Hereinafter, regarding the acoustic wave resonant circuit 11E according to the present example, description of configurations the same or substantially the same as those of the acoustic wave resonant circuit 11A according to Example 2 will be omitted, and the description will focus on differences.

As illustrated in FIG. 18A, the IDT electrode of the series-arm resonator 111E includes the multiple electrode fingers 61a (first electrode fingers) and the multiple electrode fingers 61b (second electrode fingers) arranged parallel or substantially parallel to one another, the busbar electrode 62a (first busbar electrode) interconnecting one end of each of the multiple electrode fingers 61a, and the busbar electrode 62b (second busbar electrode) interconnecting one end of each of the multiple electrode fingers 61b. The multiple electrode fingers 61a and the multiple electrode fingers 61b are interposed between the busbar electrodes 62a and 62b arranged to face each other.

Here, each of the electrode fingers 61a includes modified-shape portions 71a and 72a each having a width greater than the width of the electrode finger 61a at one end of each of the multiple electrode fingers 61a, and each of the electrode fingers 61b includes modified-shape portions 71b and 72b each having a width greater than the width of the electrode finger 61b at one end of each of the multiple electrode fingers 61b. The length of the modified-shape portion 71a in the extension direction (y-axis direction) in region 1 is different from the length of the modified-shape portion 72a in the extension direction (y-axis direction) in region 2. Similarly, the length of the modified-shape portion 71b in the extension direction (y-axis direction) in region 1 is different from the length of the modified-shape portion 72b in the extension direction (y-axis direction) in region 2. Instead of, or in addition to, making the length of the modified-shape portion 71a in region 1 and the length of the modified-shape portion 72a in region 2 different, the width of the modified-shape portion 71a in region 1 and the width of the modified-shape portion 72a in region 2 may be made different. Similarly, instead of, or in addition to, making the length of the modified-shape portion 71b in region 1 and the length of the modified-shape portion 72b in region 2 different, the width of the modified-shape portion 71b in region 1 and the width of the modified-shape portion 72b in region 2 may be made different.

It is generally known that, when the IDT electrode of an acoustic wave resonator has a 2D piston structure, transverse mode ripples can be reduced or prevented.

According to the above configuration of the present example, since the shapes of the modified-shape portions in region 1 and region 2 of the series-arm resonator 111E are made different from each other, transverse mode ripples can be dispersed. It is thus possible to provide a filter with reduced Rayleigh wave ripples and reduced transverse mode ripples.

The series-arm resonator 112E may also have a modified-shape-portion structure similar to that of the series-arm resonator 111E. This makes it possible to further reduce or prevent transverse mode ripples generated in the acoustic wave resonant circuit 11E.

It is sufficient that the modified-shape portion 71a is included in at least one of the electrode fingers 61a in region 1, and that the modified-shape portion 72a is included in at least one of the electrode fingers 61a in region 2. Similarly, it is sufficient that the modified-shape portion 71b is included in at least one of the electrode fingers 61b in region 1, and that the modified-shape portion 72b is included in at least one of the electrode fingers 61b in region 2.

FIG. 18B is a plan view illustrating an electrode configuration of a series-arm resonator 111F defining a portion of an acoustic wave resonant circuit 11F according to Example 8 of an example embodiment of the present invention. The acoustic wave resonant circuit 11F according to Example 8 includes series-arm resonators 111F and 112F connected in series with each other. As compared with the acoustic wave resonant circuit 11A according to Example 2, the acoustic wave resonant circuit 11F according to the present example differs in that each of the IDT electrodes of the series-arm resonators 111F and 112F has a 3D piston structure. Hereinafter, regarding the acoustic wave resonant circuit 11F according to the present example, description of configurations the same or substantially the same as those of the acoustic wave resonant circuit 11A according to Example 2 will be omitted, and the description will focus on differences.

As illustrated in FIG. 18B, the IDT electrode of the series-arm resonator 111F includes the multiple electrode fingers 61a (first electrode fingers) and the multiple electrode fingers 61b (second electrode fingers) arranged parallel or substantially parallel to one another, the busbar electrode 62a (first busbar electrode) interconnecting one end of each of the multiple electrode fingers 61a, and the busbar electrode 62b (second busbar electrode) interconnecting one end of each of the multiple electrode fingers 61b. The multiple electrode fingers 61a and the multiple electrode fingers 61b are interposed between the busbar electrodes 62a and 62b arranged to face each other.

Here, the IDT electrode of the series-arm resonator 111F includes mass-loading films 73a and 74a layered on portions of the electrode fingers 61a in the extension direction, and mass-loading films 73b and 74b layered on portions of the electrode fingers 61b in the extension direction. The length of the mass-loading film 73a in the extension direction (y-axis direction) in region 1 is different from the length of the mass-loading film 74a in the extension direction (y-axis direction) in region 2. Similarly, a length V1 of the mass-loading film 73b in the extension direction (y-axis direction) in region 1 is different from a length V2 of the mass-loading film 74b in the extension direction (y-axis direction) in region 2. Instead of, or in addition to, making the length of the mass-loading film in region 1 and the length of the mass-loading film in region 2 different, the film thickness of the mass-loading film in region 1 and the film thickness of the mass-loading film in region 2 may be made different.

According to the above configuration of the present example, since the shapes of the mass-loading films in region 1 and region 2 of the series-arm resonator 111F are made different from each other, transverse mode ripples can be dispersed. It is thus possible to provide a filter with reduced Rayleigh wave ripples and reduced transverse mode ripples.

The series-arm resonator 112F may also have a mass-loading-film structure similar to that of the series-arm resonator 111F. This makes it possible to further reduce or prevent transverse mode ripples generated in the acoustic wave resonant circuit 11F.

FIG. 18C is a plan view illustrating an electrode configuration of a series-arm resonator 111G defining a portion of an acoustic wave resonant circuit 11G according to Example 9 of an example embodiment of the present invention. The acoustic wave resonant circuit 11G according to Example 9 includes series-arm resonators 111G and 112G connected in series with each other. As compared with the acoustic wave resonant circuit 11F according to Example 8, the acoustic wave resonant circuit 11G according to this example differs in the shapes of mass-loading films provided on the series-arm resonators 111G and 112G. Hereinafter, regarding the acoustic wave resonant circuit 11G according to the present example, description of configurations the same or substantially the same those of the acoustic wave resonant circuit 11F according to Example 8 will be omitted, and the description will focus on differences.

As illustrated in FIG. 18C, the IDT electrode of the series-arm resonator 111G includes mass-loading films 75a and 76a layered on portions of the electrode fingers 61a in the extension direction, and mass-loading films 75b and 76b layered on portions of the electrode fingers 61b in the extension direction. The length in the extension direction (y-axis direction), film thickness, and material of the mass-loading film 75a in region 1 are the same or substantially the same as the length in the extension direction (y-axis direction), film thickness, and material of the mass-loading film 76a in region 2. Similarly, a length V3 in the extension direction (y-axis direction), film thickness, and material of the mass-loading film 75b in region 1 are the same or substantially the same as a length V4 in the extension direction (y-axis direction), film thickness, and material of the mass-loading film 76b in region 2.

According to the above configuration of the present example, since the shapes and materials of the mass-loading films in region 1 and region 2 of the series-arm resonator 111G are the same or substantially the same, the precision of the lift-off process used to form the mass-loading films is improved, thus simplifying the manufacturing process. It is thus possible to provide a filter with reduced Rayleigh wave ripples and reduced transverse mode ripples through a simplified manufacturing process.

The series-arm resonator 112G may also have a mass-loading-film structure the same as or similar to that of the series-arm resonator 111G. This makes it possible to further reduce or prevent transverse mode ripples generated in the acoustic wave resonant circuit 11G.

In the first acoustic wave resonant circuits according to Examples 1 to 9, at least one of the series-connected multiple acoustic wave resonators may include multiple reflector electrodes having different reflector-electrode-finger pitches and different duties.

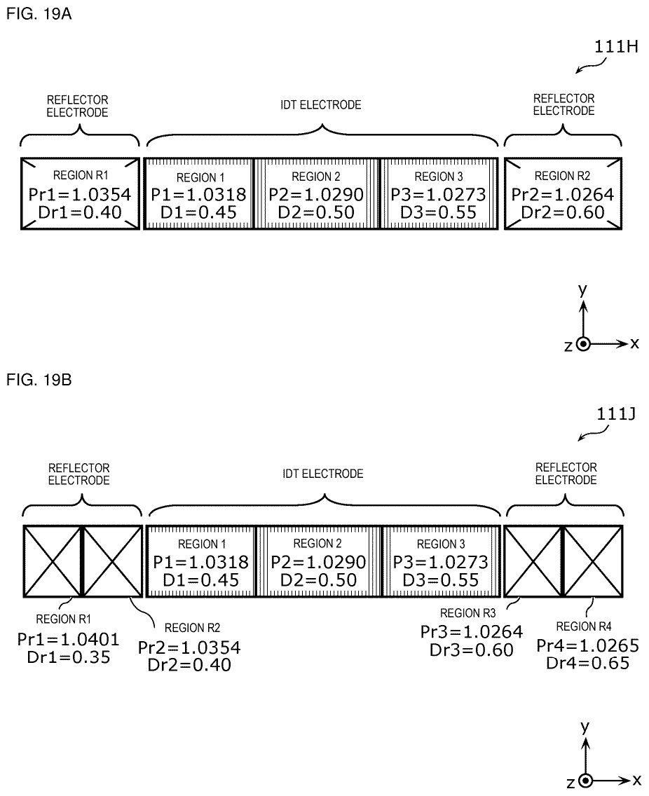

FIG. 19A is a plan view illustrating an electrode configuration of an acoustic wave resonator defining a portion of a first acoustic wave resonant circuit according to Modification 1 of an example embodiment of the present invention. The first acoustic wave resonant circuit according to Modification 1 includes multiple series-arm resonators connected in series with one another, and at least one of the series-connected multiple acoustic wave resonators may include a series-arm resonator 111H illustrated in FIG. 19A. The series-arm resonator 111H includes an IDT electrode including three electrode-finger regions (regions 1, 2, and 3), and reflector electrodes including two reflector-electrode-finger regions (regions R1 and R2), respectively. The reflector electrodes are arranged at end portions of the IDT electrode in the x-axis direction. For example, duty D1 of region 1 is about 0.45 (wavelength λ1 is about 2.0635 μm), duty D2 of region 2 is about 0.50 (wavelength λ2 is about 2.0580 μm), and duty D3 of region 3 is about 0.55 (wavelength λ3 is about 2.0545 μm). Also, for example, duty Dr1 of region R1 is about 0.40 (wavelength λr1 is about 2.0708 μm), and duty Dr2 of region R2 is about 0.60 (wavelength λr2 is about 2.0528 μm). That is, in the series-arm resonator 111H, in the IDT electrode, when the electrode-finger regions are compared, the electrode-finger pitch P, which is the interval between adjacent electrode fingers, decreases as the duty D increases. In the reflector electrode, the two reflector-electrode-finger regions R1 and R2 have different duties Dr, and different reflector-electrode-finger pitches Pr. According to this configuration, for example, it is possible to provide an acoustic wave device with reduced Rayleigh wave ripples. In the series-arm resonator 111H, it is sufficient that the number of electrode-finger regions of the IDT electrode is two or more, and that the number of reflector-electrode-finger regions be two or more.

FIG. 19B is a plan view illustrating an electrode configuration of an acoustic wave resonator defining a portion of a first acoustic wave resonant circuit according to Modification 2 of an example embodiment of the present invention. The first acoustic wave resonant circuit according to Modification 2 includes multiple series-arm resonators connected in series with one another, and at least one of the series-connected multiple acoustic wave resonators may include a series-arm resonator 111J illustrated in FIG. 19B. The series-arm resonator 111J includes an IDT electrode including three electrode-finger regions (regions 1, 2, and 3), and reflector electrodes including four reflector-electrode-finger regions (regions R1, R2, R3, and R4). The reflector electrodes are arranged at end portions of the IDT electrode in the x-axis direction. For example, duties D1 to D3 of regions 1 to 3 are the same or substantially the same as duties D1 to D3 of regions 1 to 3 of the series-arm resonator 111H. Also, for example, duty Dr1 of region R1 is about 0.35 (wavelength λr1 is about 2.0801 μm), duty Dr2 of region R2 is about 0.40 (wavelength λr2 is about 2.0708 μm), duty Dr3 of region R3 is about 0.60 (wavelength λr2 is about 2.0528 μm), and duty Dr4 of region R4 is about 0.65 (wavelength λr2 is about 2.0530 μm). That is, in the series-arm resonator 111J, in the IDT electrode, when the electrode-finger regions are compared, the electrode-finger pitch P, which is the interval between adjacent electrode fingers, decreases as the duty D increases. In the reflector electrodes, four reflector-electrode-finger regions R1 to R4 have different duties Dr, and different reflector-electrode-finger pitches Pr. According to this configuration, it is possible to provide an acoustic wave device with reduced Rayleigh wave ripples. In the series-arm resonator 111J, for example, it is sufficient that the number of electrode-finger regions of the IDT electrode is two or more, and that the number of reflector-electrode-finger regions be two or more.

As described above, the filter 10 according to the present example embodiment includes multiple acoustic wave resonant circuits, wherein the acoustic wave resonant circuit 11 among the multiple acoustic wave resonant circuits includes the series-arm resonators 111 to 113 connected in series with one another, each of the series-arm resonators 111 to 113 includes an IDT electrode disposed on the piezoelectric substrate 50 and including multiple electrode fingers parallel or substantially parallel to one another, the IDT electrode included in each of the series-arm resonators 111 to 113 is divided into multiple electrode-finger regions having different duties D, each electrode-finger region being defined as a region where two or more electrode fingers having an equal or substantially equal duty are consecutively arranged, and, when the multiple electrode-finger regions are compared, an electrode-finger pitch, which is an interval between adjacent electrode fingers, decreases as the duty D increases.

According to this configuration, the resonant frequency and the anti-resonant frequency of the main mode generated in different electrode-finger regions within one IDT electrode can be respectively made to coincide with each other, while the resonant frequency and the anti-resonant frequency of the Rayleigh wave mode generated in these different electrode-finger regions can be respectively dispersed. As a result, a single divided (series-arm) resonator makes it possible to reduce or prevent ripples due to the Rayleigh wave mode without deteriorating the resonance characteristics of the main mode. It is thus possible to provide the compact filter 10 with reduced ripples due to the Rayleigh wave mode without increasing the number of series-connected resonator sections of the acoustic wave resonant circuit 11.

Additionally, for example, in the filter 10, the number of electrode fingers included in each of the multiple electrode-finger regions is about 10% or more of the number of electrode fingers included in the IDT electrode.

Accordingly, as compared with a case where the IDT electrode includes only one electrode-finger region (duty variation region ratio=0%), Rayleigh wave ripples can be reduced.

Moreover, for example, in the filter according to Example 2, all of the electrode-finger regions of the acoustic wave resonant circuit 11A have different duties.

According to this configuration, because the dispersion effect of the resonant frequency and the anti-resonant frequency of the Rayleigh wave mode generated in all of the electrode-finger regions of the acoustic wave resonant circuit 11A can be maximized, Rayleigh wave ripples can be reduced the most.

Also, for example, in the filter according to Example 4, the acoustic wave resonant circuit 11C includes the series-arm resonators 111C and 112C, the IDT electrode of the series-arm resonator 111C and the IDT electrode of the series-arm resonator 112C are arranged adjacent to each other in a first direction, which is the electrode finger extension direction, on the main surface of the piezoelectric substrate 50, and region 3 with the maximum duty D among regions 1 to 3 of the series-arm resonator 111C, and region 4 with the maximum duty D among regions 4 to 6 of the series-arm resonator 112C do not overlap in the extension direction.

According to this configuration, the heat generation of the acoustic wave resonant circuit 11C can be dispersed, and the electric power handling capability of the acoustic wave resonant circuit 11C can be improved.

Furthermore, for example, in the filter according to Example 4, regions 1 to 3 of the series-arm resonator 111C are arranged in descending order of duty D in a second direction parallel or substantially parallel to the main surface and perpendicular or substantially perpendicular to the first direction, and regions 4 to 6 of the series-arm resonator 112C are arranged in descending order of duty D in a third direction opposite to the second direction.

According to this configuration, by reversing the direction in which the duty D of the electrode-finger regions increases/decreases between the adjacent series-arm resonators 111C and 112C, the heat generation of the acoustic wave resonant circuit 11C can be dispersed, and the electric power handling capability of the acoustic wave resonant circuit 11C can be improved.

Additionally, for example, in the filter according to Example 5, the acoustic wave resonant circuit 11D includes the series-arm resonators 111D and 112D, and the ratio of the overlap width V of the IDT electrode included in the series-arm resonator 111D to the length of the IDT electrode in the direction perpendicular to the electrode fingers is different from the ratio of the overlap width V of the IDT electrode included in the series-arm resonator 112D to the length of the IDT electrode in the direction perpendicular to the electrode fingers.

According to this configuration, since the aspect ratio is made different between the series-connected series-arm resonators 111D and 112D, transverse mode ripples can be dispersed. It is thus possible to provide a filter with reduced Rayleigh wave ripples and reduced transverse mode ripples.

For example, in the filter according to Example 7, the IDT electrode of the series-arm resonator 111E includes the multiple electrode fingers 61a and the multiple electrode fingers 61b arranged parallel or substantially parallel to one another, the busbar electrode 62a interconnecting one end of each of the multiple electrode fingers 61a, and the busbar electrode 62b interconnecting one end of each of the multiple electrode fingers 61b, the busbar electrode 62b facing the busbar electrode 62a with the electrode fingers 61a and 61b interposed therebetween. Each of the electrode fingers 61a includes the modified-shape portions 71a and 72a each having a width greater than the width at one end of the electrode finger 61a, and each of the electrode fingers 61b includes the modified-shape portions 71b and 72b each having a width greater than the width at one end of the electrode finger 61b. At least one of the width and the length of the modified-shape portion 71a in region 1 and the modified-shape region 72a in region 2 is different between the regions, and at least one of the width and the length of the modified-shape portion 71b in region 1 and the modified-shape region 72b in region 2 is different between the regions.

According to this configuration, since the shapes of the modified-shape portions in region 1 and region 2 of the series-arm resonator 111E are made different, transverse mode ripples can be dispersed. It is thus possible to provide a filter with reduced Rayleigh wave ripples and reduced transverse mode ripples.

Moreover, in the filter according to Example 8, the IDT electrode of the series-arm resonator 111F includes the mass-loading films 73a and 74a layered on portions of the electrode fingers 61a in the extension direction, and the mass-loading films 73b and 74b layered on portions of the electrode fingers 61b in the extension direction. At least one of the length in the extension direction and the film thickness of the mass-loading film 73a in region 1 and the mass-loading film 74a in region 2 is different between the regions, and at least one of the length in the extension direction and the film thickness of the mass-loading film 73b in region 1 and the mass-loading film 74b in region 2 is different between the regions.

According to this configuration, since the shapes of the mass-loading films in regions 1 and 2 of the series-arm resonator 111F are made different, transverse mode ripples can be dispersed. It is thus possible to provide a filter with reduced Rayleigh wave ripples and reduced transverse mode ripples.

Moreover, for example, in the filter according to Example 9, the IDT electrode of the series-arm resonator 111G further includes the mass-loading films 75a and 76a layered on portions of the electrode fingers 61a in the extension direction, and the mass-loading films 75b and 76b layered on portions of the electrode fingers 61b in the extension direction. At least one of the length in the extension direction and the film thickness of the mass-loading film 75a in region 1 and the mass-loading film 76a in region 2 is the same or substantially the same between the regions, and at least one of the length in the extension direction and the film thickness of the mass-loading film 73b in region 1 and the mass-loading film 74b in region 2 is the same or substantially the same between the regions.

According to this configuration, since the shapes of the mass-loading films in region 1 and region 2 of the series-arm resonator 111G are the same or substantially the same, the precision of the lift-off process used to form the mass-loading films is improved, thus simplifying the manufacturing process. It is thus possible to provide a filter with reduced Rayleigh wave ripples and reduced transverse mode ripples through a simplified manufacturing process.

For example, a multiplexer 1 according to an example embodiment includes the common terminal 100, the filter 10 or any of the filters according to Examples 2 to 9 connected to the common terminal 100, and the filter 20 connected to the common terminal 100.

According to this configuration, it is possible to provide the multiplexer 1 in which a Rayleigh wave response generated in the filter 10 or in any of the filters according to Examples 2 to 9 is reduced or prevented.

For example, in the multiplexer 1, the acoustic wave resonant circuit 11 is most closely connected to the common terminal 100 among the multiple acoustic wave resonant circuits constituting the filter.

According to this configuration, return loss at a frequency at which a Rayleigh wave spurious response occurs when the filter 10 or any of the filters according to Examples 2 to 9 is viewed from the common terminal 100 can be effectively reduced. It is thus possible to reduce or prevent, at the above-described occurrence frequency, deterioration of the transmission characteristics of the filter 20 connected to the common terminal 100.

For example, in the multiplexer 1, the series-arm resonator 141 which is most closely connected to the common terminal 100 among the series-arm resonators 141 to 143 included in the acoustic wave resonant circuit 14 of the filter 10A has the largest average duty D_{AVE} among the series-arm resonators 141 to 143.

According to this configuration, intermodulation distortion generated by the filter 10A can be effectively reduced or prevented.

Also, for example, in the multiplexer 1, the filter 10 is a band-stop filter with a stopband.

According to this configuration, Rayleigh wave ripples in the passband of the filter 10 can be reduced or prevented. Additionally, since a signal in the Rayleigh wave mode generated in the filter 10 can be reduced or prevented from coupling into the filter 20 through the common terminal 100, deterioration of attenuation characteristics of the filter 20 can be reduced or prevented.

Moreover, for example, in the multiplexer 1, the filter 10 is a band-pass filter with a passband.

According to this configuration, Rayleigh wave ripples generated on the lower frequency side of the passband of the filter 10 can be reduced or prevented. Additionally, since a signal in the Rayleigh wave mode generated in the filter 10 can be reduced or prevented from coupling into the filter 20 through the common terminal 100, deterioration of transmission characteristics or attenuation characteristics of the filter 20 can be reduced or prevented.

Although the acoustic wave devices and multiplexers according to the present invention have been described above based on example embodiments and examples, the present invention is not limited to the example embodiments and the examples described above. Modifications obtained by applying various modifications conceived by those skilled in the art to the above-described example embodiments and the examples without departing from the spirit of the present invention, as well as various devices incorporating the acoustic wave devices and multiplexers according to example embodiments of the present invention, are also included in the present invention.

For example, although the above-described example embodiments mainly describe an example in which the first acoustic wave resonant circuit includes multiple series-arm resonators connected in series with one another, it is sufficient that, in the acoustic wave devices and multiplexers according to example embodiments of the present invention, the first acoustic wave resonant circuit includes multiple acoustic wave resonators connected in series with one another, and the first acoustic wave resonant circuit may instead include multiple parallel-arm resonators connected in series with one another. Even in this case, it is possible to provide acoustic wave devices and multiplexers with reduced Rayleigh wave ripples.

Furthermore, for example, in the acoustic wave devices and multiplexers according to the example embodiments and examples, matching elements such as, for example, inductors and capacitors, as well as switch circuits, may be connected between the respective components.

The resonant frequency and the anti-resonant frequency discussed in the above example embodiments and examples are derived, for example, by bringing RF probes into contact with the two input/output electrodes of each acoustic wave resonator and measuring the reflection characteristics.

Example embodiments of the present invention can be widely used as, for example, a transmission/reception filter and a multiplexer used in the front end of a wireless communication terminal, where low loss within the passband and high attenuation outside the passband are required.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a plurality of acoustic wave resonant circuits; wherein
among the plurality of acoustic wave resonant circuits, a first acoustic wave resonant circuit includes a plurality of acoustic wave resonators connected in series with one another;
each of the plurality of acoustic wave resonators includes an IDT (InterDigital Transducer) electrode on a substrate including piezoelectric properties, and the IDT electrode includes a plurality of electrode fingers parallel or substantially parallel to one another;
the IDT electrode included in each of the plurality of acoustic wave resonators is divided into a plurality of electrode-finger regions including different duties, each electrode-finger region being defined as a region where two or more electrode fingers including an equal duty are consecutively arranged; and
when the plurality of electrode-finger regions are compared, an electrode-finger pitch, which is an interval between adjacent electrode fingers, decreases as the duty increases.

2. The acoustic wave device according to claim 1, wherein a number of electrode fingers included in each of the plurality of electrode-finger regions is about 10% or more of a number of electrode fingers included in the IDT electrode.

3. The acoustic wave device according to claim 1, wherein all of the plurality of electrode-finger regions of the first acoustic wave resonant circuit include different duties.

4. The acoustic wave device according to claim 1, wherein
the plurality of acoustic wave resonators of the first acoustic wave resonant circuit include a first acoustic wave resonator and a second acoustic wave resonator;
the IDT electrode included in the first acoustic wave resonator and the IDT electrode included in the second acoustic wave resonator are adjacent to each other in a first direction that is an extension direction of the electrode fingers on a main surface of the substrate; and
an electrode-finger region with a largest duty among the plurality of electrode-finger regions of the first acoustic wave resonator and an electrode-finger region with a largest duty among the plurality of electrode-finger regions of the second acoustic wave resonator do not overlap each other in the extension direction.

5. The acoustic wave device according to claim 4, wherein
the plurality of electrode-finger regions of the first acoustic wave resonator are arranged in descending order of duty in a second direction parallel or substantially parallel to the main surface and perpendicular or substantially perpendicular to the first direction; and
the plurality of electrode-finger regions of the second acoustic wave resonator are arranged in descending order of duty in a third direction opposite to the second direction.

6. The acoustic wave device according to claim 1, wherein
the plurality of acoustic wave resonators of the first acoustic wave resonant circuit include a first acoustic wave resonator and a second acoustic wave resonator;
a ratio of an overlap width of the IDT electrode included in the first acoustic wave resonator to a length of the IDT electrode in a direction perpendicular or substantially perpendicular to the electrode fingers is different from a ratio of an overlap width of the IDT electrode included in the second acoustic wave resonator to a length of the IDT electrode in a direction perpendicular or substantially perpendicular to the electrode fingers.

7. The acoustic wave device according to claim 1, wherein
the IDT electrode includes:
a plurality of first electrode fingers and a plurality of second electrode fingers parallel or substantially parallel to one another;
a first busbar electrode interconnecting one end of each of the plurality of first electrode fingers; and
a second busbar electrode interconnecting one end of each of the plurality of second electrode fingers, the second busbar electrode facing the first busbar electrode with the plurality of first electrode fingers and the plurality of second electrode fingers interposed therebetween;
at least one of the plurality of first electrode fingers and the plurality of second electrode fingers includes a modified-shape portion with a width greater than a width of the first electrode finger at one end of the plurality of first electrode fingers and a width of the second electrode finger at one end of the plurality of second electrode fingers; and
at least one of the width and a length of the modified-shape portion is different among the plurality of electrode-finger regions.

8. The acoustic wave device according to claim 1, wherein
the IDT electrode further includes:
a mass-loading film on portions of the plurality of electrode fingers in the extension direction; and
at least one of a length in the extension direction and a film thickness of the mass-loading film is different among the plurality of electrode-finger regions.

9. The acoustic wave device according to claim 1, wherein
the IDT electrode further includes:
a mass-loading film on portions of the plurality of electrode fingers in the extension direction; and
at least one of a length in the extension direction and a film thickness of the mass-loading film is the same or substantially the same among the plurality of electrode-finger regions.

10. A multiplexer comprising:
a common terminal;
the acoustic wave device according to claim 1 connected to the common terminal; and
a filter connected to the common terminal.

11. The multiplexer according to claim 10, wherein the first acoustic wave resonant circuit is most closely connected to the common terminal among the plurality of acoustic wave resonant circuits.

12. The multiplexer according to claim 10, wherein an acoustic wave resonator that is most closely connected to the common terminal among the plurality of acoustic wave resonators included in the first acoustic wave resonant circuit includes a largest average duty among the plurality of acoustic wave resonators.

13. The multiplexer according to claim 10, wherein the acoustic wave device is a band-stop filter including a stopband.

14. The multiplexer according to claim 10, wherein the acoustic wave device is a band-pass filter including a passband.

15. The multiplexer according to claim 10, wherein a number of electrode fingers included in each of the plurality of electrode-finger regions is about 10% or more of a number of electrode fingers included in the IDT electrode.

16. The multiplexer according to claim 10, wherein all of the plurality of electrode-finger regions of the first acoustic wave resonant circuit include different duties.

17. The multiplexer according to claim 10, wherein
the plurality of acoustic wave resonators of the first acoustic wave resonant circuit include a first acoustic wave resonator and a second acoustic wave resonator;
the IDT electrode included in the first acoustic wave resonator and the IDT electrode included in the second acoustic wave resonator are adjacent to each other in a first direction that is an extension direction of the electrode fingers on a main surface of the substrate; and
an electrode-finger region with a largest duty among the plurality of electrode-finger regions of the first acoustic wave resonator and an electrode-finger region with a largest duty among the plurality of electrode-finger regions of the second acoustic wave resonator do not overlap each other in the extension direction.

18. The multiplexer according to claim 17, wherein
the plurality of electrode-finger regions of the first acoustic wave resonator are arranged in descending order of duty in a second direction parallel or substantially parallel to the main surface and perpendicular or substantially perpendicular to the first direction; and
the plurality of electrode-finger regions of the second acoustic wave resonator are arranged in descending order of duty in a third direction opposite to the second direction.

19. The multiplexer according to claim 10, wherein
the plurality of acoustic wave resonators of the first acoustic wave resonant circuit include a first acoustic wave resonator and a second acoustic wave resonator;
a ratio of an overlap width of the IDT electrode included in the first acoustic wave resonator to a length of the IDT electrode in a direction perpendicular or substantially perpendicular to the electrode fingers is different from a ratio of an overlap width of the IDT electrode included in the second acoustic wave resonator to a length of the IDT electrode in a direction perpendicular or substantially perpendicular to the electrode fingers.

20. The multiplexer according to claim 10, wherein
the IDT electrode includes:
a plurality of first electrode fingers and a plurality of second electrode fingers parallel or substantially parallel to one another;
a first busbar electrode interconnecting one end of each of the plurality of first electrode fingers; and
a second busbar electrode interconnecting one end of each of the plurality of second electrode fingers, the second busbar electrode facing the first busbar electrode with the plurality of first electrode fingers and the plurality of second electrode fingers interposed therebetween;
at least one of the plurality of first electrode fingers and the plurality of second electrode fingers includes a modified-shape portion with a width greater than a width of the first electrode finger at one end of the plurality of first electrode fingers and a width of the second electrode finger at one end of the plurality of second electrode fingers; and
at least one of the width and a length of the modified-shape portion is different among the plurality of electrode-finger regions.
